(19) United States
(12) Patent Application Publication
(10) Pub. No.: US 2024/0347662 A1
(43) Pub. Date: Oct. 17, 2024

(54) SEMICONDUCTOR DEVICE AND METHOD OF MAKING

(71) Applicant: Taiwan Semiconductor Manufacturing Company Limited, Hsinc-chu (TW)

(72) Inventors: Wen-Sheng WANG, Hsin-Chu (TW); Yi-Hsuan FAN, New Taipei City (TW)

(21) Appl. No.: 18/230,756

(22) Filed: Aug. 7, 2023

Related U.S. Application Data
(60) Provisional application No. 63/459,098, filed on Apr. 13, 2023.

(51) Int. Cl. H01L 31/103; H01L 31/18

(52) U.S. Cl. CPC H01L 31/1035; H01L 31/1844

(57) ABSTRACT

A semiconductor device is provided. The semiconductor device includes a substrate, a first epitaxial layer over the substrate, a second epitaxial layer over the first epitaxial layer, and a photodiode in at least one of the first epitaxial layer or the second epitaxial layer. The photodiode includes a first doped region and a second doped region over the first doped region.

### CROSS-REFERENCE TO RELATED APPLICATIONS

This application claims priority to U.S. provisional application 63/459,098, titled “SEMICONDUCTOR DEVICE AND METHOD OF MAKING” and filed on Apr. 13, 2023, which is incorporated herein by reference.

### BACKGROUND

Semiconductor devices are used in a multitude of electronic devices, such as mobile phones, laptops, desktops, tablets, watches, gaming systems, and various other industrial, commercial, and consumer electronics. Semiconductor devices generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device at a stage of fabrication, in accordance with some embodiments.

FIG. 2 illustrates a cross-sectional view of a semiconductor device at a stage of fabrication, in accordance with some embodiments.

FIG. 3 illustrates a cross-sectional view of a semiconductor device at a stage of fabrication, in accordance with some embodiments.

FIG. 4 illustrates a cross-sectional view of a semiconductor device at a stage of fabrication, in accordance with some embodiments.

FIG. 5 illustrates a cross-sectional view of a semiconductor device at a stage of fabrication, in accordance with some embodiments.

FIG. 6 illustrates a cross-sectional view of a semiconductor device at a stage of fabrication, in accordance with some embodiments.

FIG. 7 illustrates a cross-sectional view of a semiconductor device at a stage of fabrication, in accordance with some embodiments.

FIG. 8 illustrates a cross-sectional view of a semiconductor device at a stage of fabrication, in accordance with some embodiments.

FIG. 9 illustrates a cross-sectional view of a semiconductor device at a stage of fabrication, in accordance with some embodiments.

FIG. 10 illustrates a cross-sectional view of a semiconductor device at a stage of fabrication, in accordance with some embodiments.

FIG. 11 illustrates a cross-sectional view of a semiconductor device, in accordance with some embodiments.

FIG. 12 illustrates a cross-sectional view of a semiconductor device, in accordance with some embodiments.

FIG. 13 illustrates a cross-sectional view of a semiconductor device, in accordance with some embodiments.

FIG. 14 illustrates a cross-sectional view of a semiconductor device, in accordance with some embodiments.

FIG. 15 illustrates a cross-sectional view of a semiconductor device, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A semiconductor device has a substrate, a plurality of epitaxial layers over the substrate, and a photodiode in the plurality of epitaxial layers. The plurality of epitaxial layers includes dopants of a first conductivity type. The photodiode includes a first doped region having a second conductivity type different than the first conductivity type. The photodiode includes a second doped region, over the first doped region, having the first conductivity type. A first p-n junction is formed between the first doped region and a portion of an epitaxial layer underlying the first doped region. A second p-n junction is formed between the first doped region and the second doped region. The first p-n junction has a first depth relative to a surface of the semiconductor device. The first p-n junction having the first depth provides for improved quantum efficiency (QE) of the photodiode for a first range of wavelengths, such as near infrared (NIR) wavelengths. The second p-n junction has a second depth relative to the surface of the semiconductor device. The second p-n junction having the second depth provides for improved QE of the photodiode for a second range of wavelengths, such as visible wavelengths. In some embodiments, the semiconductor device operates as a sensor, such as at least one of an image sensor or a different type of sensor. Given the improved QE, the semiconductor device operates more efficiently than other sensors, such as requiring less power, being more effective in a relatively low light environment, providing a higher resolution, etc.

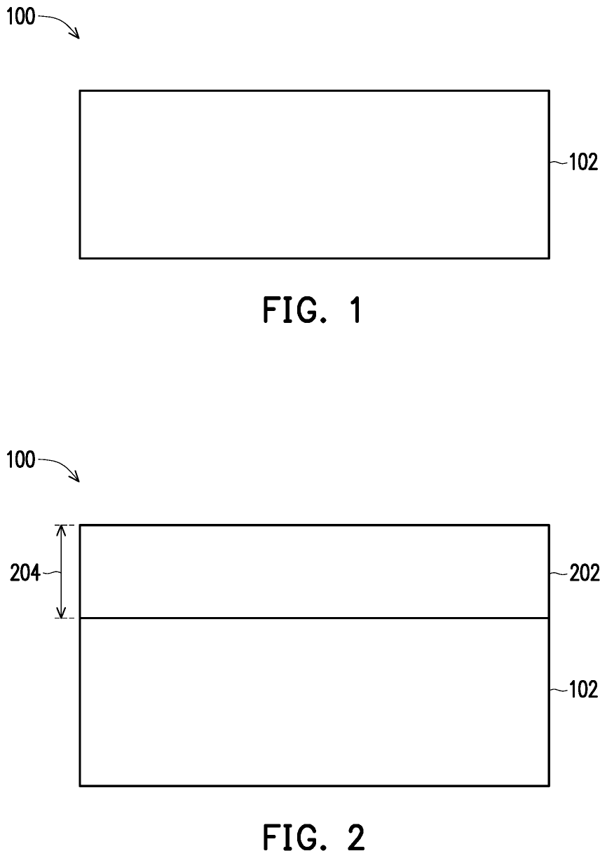

FIGS. 1-10 illustrate cross-sectional views of a semiconductor device 100 at various stages of fabrication, in accordance with some embodiments. In some embodiments, a sensor is implemented via the semiconductor device 100. The sensor comprises at least one of an image sensor, a complementary metal-oxide-semiconductor (CMOS) image sensor, a backside CMOS image sensor, or another type of sensor. Other structures and/or configurations of the semiconductor device 100 and/or the sensor are within the scope of the present disclosure.

FIG. 1 illustrates the semiconductor device 100 according to some embodiments. The semiconductor device 100 comprises a substrate 102. The substrate 102 comprises at least one of an epitaxial layer, a silicon-on-insulator (SOI) structure, a wafer, or a die formed from a wafer. The substrate 102 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The substrate 102 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the substrate 102 are within the scope of the present disclosure.

In some embodiments, the substrate 102 comprises first dopants having a first conductivity type, such as n-type or p-type. In some embodiments, the first dopants comprise at least one of nitrogen (N), phosphorus (P), beryllium (Be), boron (B), aluminum (Al), gallium (Ga), or other dopant. In some embodiments, the first dopants are p-type dopants comprising at least one of boron dopants, aluminum dopants, gallium dopants, beryllium dopants, or other p-type dopants. In some embodiments, the first dopants are n-type dopants comprising at least one of nitrogen dopants, phosphorus dopants, or other n-type dopants. In some embodiments, the substrate 102 is doped with the first dopants by at least one of ion implantation, molecular diffusion, or other suitable techniques. In some embodiments, a depth of dopants of the first dopants in the substrate 102 is controlled by increasing or decreasing a voltage used to direct the dopants into the substrate 102. In some embodiments, a first dopant concentration of the first dopants in the substrate 102 is controlled by at least one of a quantity of implantation shots of one or more implantation shots performed to direct the first dopants into the substrate 102, an implantation dose an implantation shot of the one or more implantation shots, an implantation energy level of the implantation shot, or other suitable parameter.

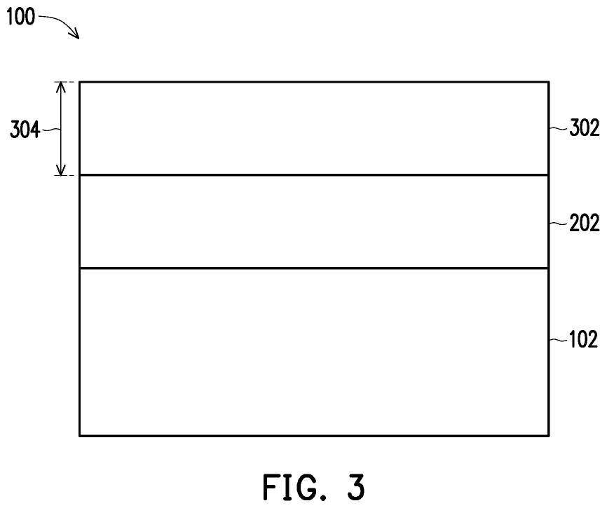

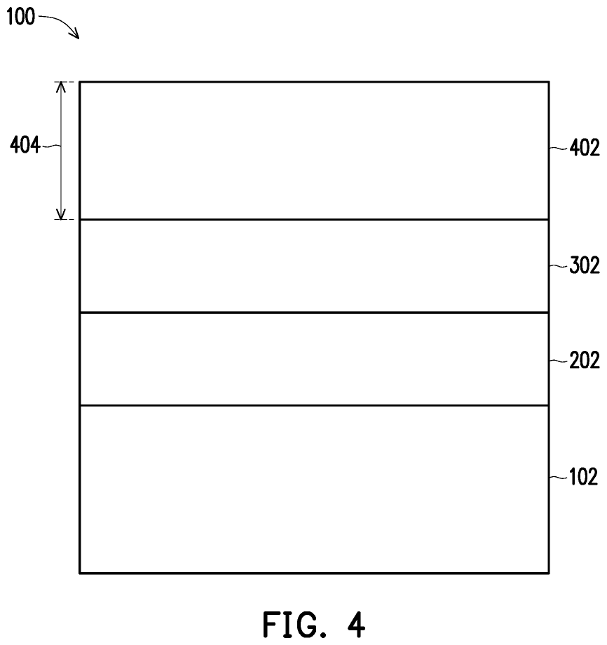

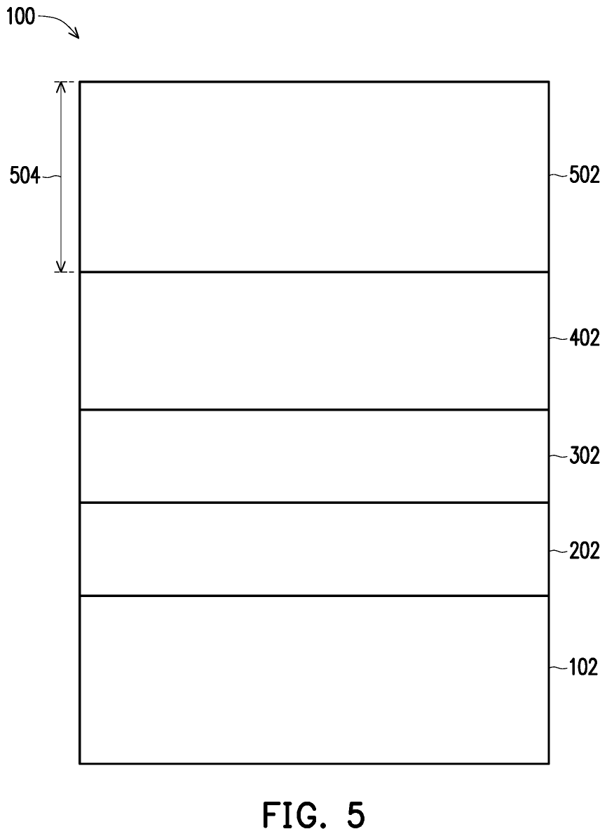

In some embodiments, a plurality of epitaxial layers is formed over the substrate 102. In some embodiments, the plurality of epitaxial layers comprise at least one of a first epitaxial layer 202 (shown in FIG. 2), a second epitaxial layer 302 (shown in FIG. 3), a third epitaxial layer 402 (shown in FIG. 4), a fourth epitaxial layer 502 (shown in FIG. 5), or other epitaxial layer.

FIG. 2 illustrates the first epitaxial layer 202 formed over the substrate 102, according to some embodiments. In some embodiments, the first epitaxial layer 202 is formed to have a first thickness 204. In some embodiments, the first epitaxial layer 202 is formed by a first epitaxial process, such as an epitaxial growth process. In some embodiments, the first epitaxial process includes at least one of molecular beam epitaxy, chemical vapor deposition (CVD), vapor-phase epitaxy (VPE), ultra-high vacuum CVD (UHV-CVD), growth, or other suitable process. In some embodiments, the first epitaxial process uses one or more precursors comprising at least one of a gas precursor, a vapor precursor, or a liquid precursor. In some embodiments, the one or more precursors interact with the substrate 102 during the first epitaxial process. Embodiments are contemplated in which the first epitaxial layer 202 is formed by at least one of physical vapor deposition (PVD), sputtering, CVD, plasma enhanced CVD (PECVD), low pressure CVD (LPCVD), atomic layer chemical vapor deposition (ALCVD), UHVCVD, reduced pressure CVD (RPCVD), atomic layer deposition (ALD), molecular beam epitaxy (MBE), liquid phase epitaxy (LPE), spin on, or other suitable techniques.

In some embodiments, the first epitaxial layer 202 is a doped layer, such as a doped epi layer. In some embodiments, the first epitaxial layer 202 comprises second dopants having the first conductivity type. In some embodiments, in the first epitaxial process, at least some of the second dopants having the first conductivity type travel from the substrate 102 to the first epitaxial layer 202. In some embodiments, at least some of the second dopants are introduced to the first epitaxial layer 202 via the first epitaxial process by at least one of (i) adding impurities to a source material of the first epitaxial process, (ii) using a dopant precursor in the first epitaxial process, or (iii) other suitable techniques. In some embodiments, at least some of the second dopants are introduced to the first epitaxial layer 202 after the first epitaxial process is performed, such as by at least one of ion implantation, molecular diffusion, or other suitable techniques.

In some embodiments, the first epitaxial layer 202 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the first epitaxial layer 202 is in direct contact with a top surface of the substrate 102. The first epitaxial layer 202 is different than the substrate 102, such as having a different material composition, such that an interface is defined between the first epitaxial layer 202 and the substrate 102. In some embodiments, the first epitaxial layer 202 does not have a material composition different than the substrate 102. An interface is nevertheless defined between the first epitaxial layer 202 and the substrate 102 because the first epitaxial layer 202 and the substrate 102 are separate, different, etc. layers (e.g., one or more measurable properties exist at the interface that would not exist and/or would have different values in a continuous, single, etc. layer (e.g., roughness, smoothness, tension, compression, conductivity, resistivity, etc.). In some embodiments, the first epitaxial layer 202 is in indirect contact with the top surface of the substrate 102, where one or more layers, such as a buffer layer, are between the first epitaxial layer 202 and the substrate 102. In some embodiments, a second dopant concentration of the second dopants in the first epitaxial layer 202 is greater than the first dopant concentration of the first dopants in the substrate 102. In some embodiments, the second dopant concentration is controlled by at least one of a parameter of the first epitaxial process or other suitable parameter.

FIG. 3 illustrates the second epitaxial layer 302 formed over the first epitaxial layer 202, according to some embodiments. In some embodiments, the second epitaxial layer 302 is formed to have a second thickness 304. In some embodiments, the second thickness 304 is greater than the first thickness 204 of the first epitaxial layer 202. In some embodiments, the second epitaxial layer 302 is formed by a second epitaxial process, such as an epitaxial growth process. In some embodiments, the second epitaxial process includes at least one of molecular beam epitaxy, CVD, VPE, UHV-CVD, growth, or other suitable process. In some embodiments, the second epitaxial process uses one or more precursors comprising at least one of a gas precursor, a vapor precursor, or a liquid precursor. In some embodiments, the one or more precursors interact with at least one of the first epitaxial layer 202 or the substrate 102 during the second epitaxial process. Embodiments are contemplated in which the second epitaxial layer 302 is formed by at least one of PVD, sputtering, CVD, PECVD, LPCVD, ALCVD, UHVCVD, RPCVD, ALD, MBE, LPE, spin on, growth, or other suitable techniques.

In some embodiments, the second epitaxial layer 302 is a doped layer, such as a doped epi layer. In some embodiments, the second epitaxial layer 302 comprises third dopants having the first conductivity type. In some embodiments, in the second epitaxial process, at least some of the third dopants having the first conductivity type travel from at least one of the first epitaxial layer 202 or the substrate 102 to the second epitaxial layer 302. In some embodiments, at least some of the third dopants are introduced to the second epitaxial layer 302 via the second epitaxial process by at least one of (i) adding impurities to a source material of the second epitaxial process, (ii) using a dopant precursor in the second epitaxial process, or (iii) other suitable techniques. In some embodiments, at least some of the third dopants are introduced to the second epitaxial layer 302 after the second epitaxial process is performed, such as by at least one of ion implantation, molecular diffusion, or other suitable techniques.

In some embodiments, the second epitaxial layer 302 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the second epitaxial layer 302 is in direct contact with a top surface of the first epitaxial layer 202. The second epitaxial layer 302 is different than the first epitaxial layer 202, such as having a different material composition, such that an interface is defined between the second epitaxial layer 302 and the first epitaxial layer 202. In some embodiments, the second epitaxial layer 302 does not have a material composition different than the first epitaxial layer 202. An interface is nevertheless defined between the second epitaxial layer 302 and the first epitaxial layer 202 because the second epitaxial layer 302 and the first epitaxial layer 202 are separate, different, etc. layers (e.g., one or more measurable properties exist at the interface that would not exist and/or would have different values in a continuous, single, etc. layer (e.g., roughness, smoothness, tension, compression, conductivity, resistivity, etc.). In some embodiments, the second epitaxial layer 302 is in indirect contact with the top surface of the first epitaxial layer 202, where one or more layers, such as a buffer layer, are between the second epitaxial layer 302 and the first epitaxial layer 202. In some embodiments, a third dopant concentration of the third dopants in the second epitaxial layer 302 is less than the second dopant concentration of the second dopants in the first epitaxial layer 202. In some embodiments, the third dopant concentration is controlled by at least one of a parameter of the second epitaxial process or other suitable parameter.

FIG. 4 illustrates the third epitaxial layer 402 formed over the second epitaxial layer 302, according to some embodiments. In some embodiments, the third epitaxial layer 402 is formed to have a third thickness 404. In some embodiments, the third thickness 404 is greater than the second thickness 304 of the second epitaxial layer 302. In some embodiments, the third epitaxial layer 402 is formed by a third epitaxial process, such as an epitaxial growth process. In some embodiments, the third epitaxial process includes at least one of molecular beam epitaxy, CVD, VPE, UHV-CVD, growth, or other suitable process. In some embodiments, the third epitaxial process uses one or more precursors comprising at least one of a gas precursor, a vapor precursor, or a liquid precursor. In some embodiments, the one or more precursors interact with at least one of the second epitaxial layer 302, the first epitaxial layer 202, or the substrate 102 during the third epitaxial process. Embodiments are contemplated in which the third epitaxial layer 402 is formed by at least one of PVD, sputtering, CVD, PECVD, LPCVD, ALCVD, UHVCVD, RPCVD, ALD, MBE, LPE, spin on, growth, or other suitable techniques.

In some embodiments, the third epitaxial layer 402 is a doped layer, such as a doped epi layer. In some embodiments, the third epitaxial layer 402 comprises fourth dopants having the first conductivity type. In some embodiments, in the third epitaxial process, at least some of the fourth dopants having the first conductivity type travel from at least one of the second epitaxial layer 302, the first epitaxial layer 202, or the substrate 102 to the third epitaxial layer 402. In some embodiments, at least some of the fourth dopants are introduced to the third epitaxial layer 402 via the third epitaxial process by at least one of (i) adding impurities to a source material of the third epitaxial process, (ii) using a dopant precursor in the third epitaxial process, or (iii) other suitable techniques. In some embodiments, at least some of the fourth dopants are introduced to the third epitaxial layer 402 after the third epitaxial process is performed, such as by at least one of ion implantation, molecular diffusion, or other suitable techniques.

In some embodiments, the third epitaxial layer 402 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the third epitaxial layer 402 is in direct contact with a top surface of the second epitaxial layer 302. The third epitaxial layer 402 is different than the second epitaxial layer 302, such as having a different material composition, such that an interface is defined between the third epitaxial layer 402 and the second epitaxial layer 302. In some embodiments, the third epitaxial layer 402 does not have a material composition different than the second epitaxial layer 302. An interface is nevertheless defined between the third epitaxial layer 402 and the second epitaxial layer 302 because the third epitaxial layer 402 and the second epitaxial layer 302 are separate, different, etc. layers (e.g., one or more measurable properties exist at the interface that would not exist and/or would have different values in a continuous, single, etc. layer (e.g., roughness, smoothness, tension, compression, conductivity, resistivity, etc.). In some embodiments, the third epitaxial layer 402 is in indirect contact with the top surface of the second epitaxial layer 302, where one or more layers, such as a buffer layer, are between the third epitaxial layer 402 and the second epitaxial layer 302. In some embodiments, a fourth dopant concentration of the fourth dopants in the third epitaxial layer 402 is less than the third dopant concentration of the third dopants in the second epitaxial layer 302. In some embodiments, the fourth dopant concentration is controlled by at least one of a parameter of the third epitaxial process or other suitable parameter.

FIG. 5 illustrates the fourth epitaxial layer 502 formed over the third epitaxial layer 402, according to some embodiments. In some embodiments, the fourth epitaxial layer 502 is formed to have a fourth thickness 504. In some embodiments, the fourth thickness 504 is greater than the third thickness 404 of the third epitaxial layer 402. In some embodiments, the fourth epitaxial layer 502 is formed by a fourth epitaxial process, such as an epitaxial growth process. In some embodiments, the fourth epitaxial process includes at least one of molecular beam epitaxy, CVD, VPE, UHV-CVD, growth, or other suitable process. In some embodiments, the fourth epitaxial process uses one or more precursors comprising at least one of a gas precursor, a vapor precursor, or a liquid precursor. In some embodiments, the one or more precursors interact with at least one of the third epitaxial layer 402, the second epitaxial layer 302, the first epitaxial layer 202, or the substrate 102 during the fourth epitaxial process. Embodiments are contemplated in which the fourth epitaxial layer 502 is formed by at least one of PVD, sputtering, CVD, PECVD, LPCVD, ALCVD, UHVCVD, RPCVD, ALD, MBE, LPE, spin on, growth, or other suitable techniques.

In some embodiments, the fourth epitaxial layer 502 is a doped layer, such as a doped epi layer. In some embodiments, the fourth epitaxial layer 502 comprises fifth dopants having the first conductivity type. In some embodiments, in the fourth epitaxial process, at least some of the fifth dopants having the first conductivity type travel from at least one of the third epitaxial layer 402, the second epitaxial layer 302, the first epitaxial layer 202, or the substrate 102 to the fourth epitaxial layer 502. In some embodiments, at least some of the fifth dopants are introduced to the fourth epitaxial layer 502 via the fourth epitaxial process by at least one of (i) adding impurities to a source material of the fourth epitaxial process, (ii) using a dopant precursor in the fourth epitaxial process, (iii) diffusion, or (iv) other suitable techniques. In some embodiments, at least some of the fifth dopants are introduced to the fourth epitaxial layer 502 after the fourth epitaxial process is performed, such as by at least one of ion implantation, molecular diffusion, or other suitable techniques.

In some embodiments, the fourth epitaxial layer 502 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the fourth epitaxial layer 502 is in direct contact with a top surface of the third epitaxial layer 402. The fourth epitaxial layer 502 is different than the third epitaxial layer 402, such as having a different material composition, such that an interface is defined between the fourth epitaxial layer 502 and the third epitaxial layer 402. In some embodiments, the fourth epitaxial layer 502 does not have a material composition different than the third epitaxial layer 402. An interface is nevertheless defined between the fourth epitaxial layer 502 and the third epitaxial layer 402 because the fourth epitaxial layer 502 and the third epitaxial layer 402 are separate, different, etc. layers (e.g., one or more measurable properties exist at the interface that would not exist and/or would have different values in a continuous, single, etc. layer (e.g., roughness, smoothness, tension, compression, conductivity, resistivity, etc.). In some embodiments, the fourth epitaxial layer 502 is in indirect contact with the top surface of the third epitaxial layer 402, where one or more layers, such as a buffer layer, are between the fourth epitaxial layer 502 and the third epitaxial layer 402. In some embodiments, a fifth dopant concentration of the fifth dopants in the fourth epitaxial layer 502 is less than the fourth dopant concentration of the fourth dopants in the third epitaxial layer 402. In some embodiments, the fifth dopant concentration is controlled by at least one of a parameter of the fourth epitaxial process or other suitable parameter.

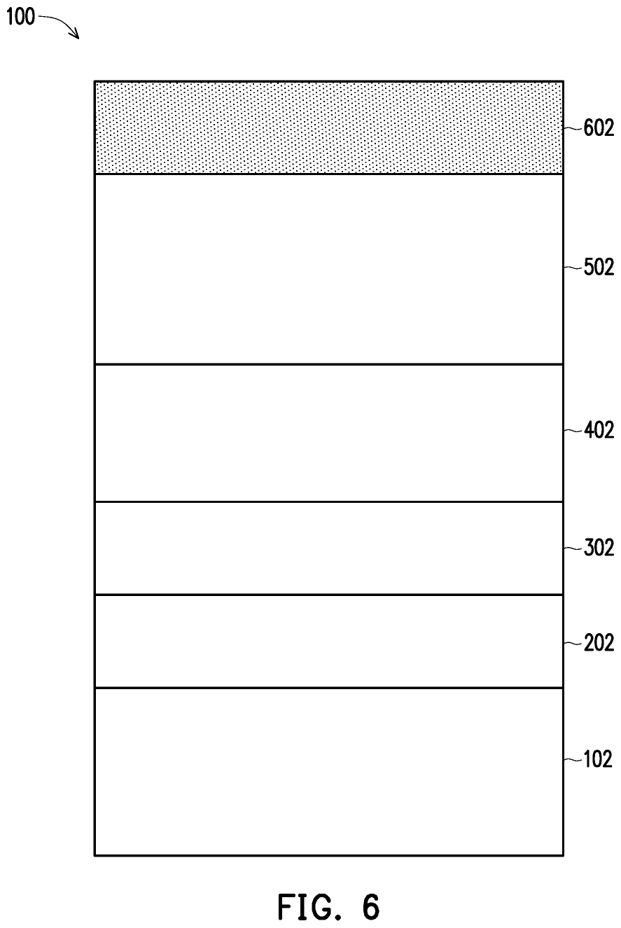

FIG. 6 illustrates a first photoresist 602 formed over the fourth epitaxial layer 502, according to some embodiments. The first photoresist 602 at least one of overlies the fourth epitaxial layer 502, is in direct contact with a top surface of the fourth epitaxial layer 502, or is in indirect contact with the top surface of the fourth epitaxial layer 502. The first photoresist 602 is formed by at least one of PVD, sputtering, CVD, PECVD, LPCVD, ALCVD, UHVCVD, RPCVD, ALD, MBE, LPE, spin on, growth, or other suitable techniques.

In some embodiments, the first photoresist 602 comprises a light-sensitive material, where properties, such as solubility, of the first photoresist 602 are affected by light. The first photoresist 602 is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

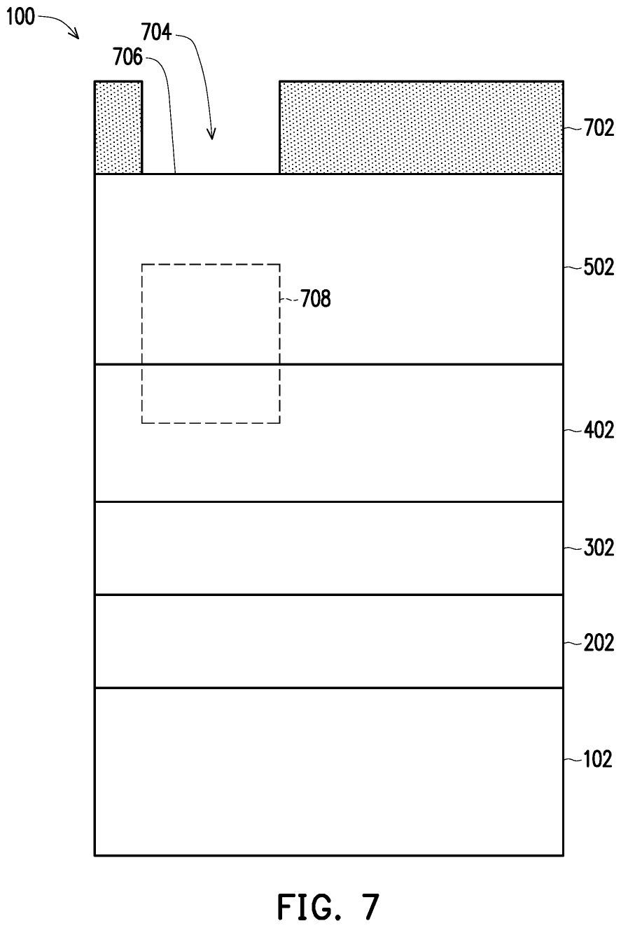

FIG. 7 illustrates a first patterned photoresist 702 formed from the first photoresist 602, according to some embodiments. In some embodiments, the first patterned photoresist 702 defines an opening 704 exposing a portion 706 of a top surface of the fourth epitaxial layer 502. Even though one opening in the first patterned photoresist 702 is depicted, any number of openings in the first patterned photoresist 702 are contemplated.

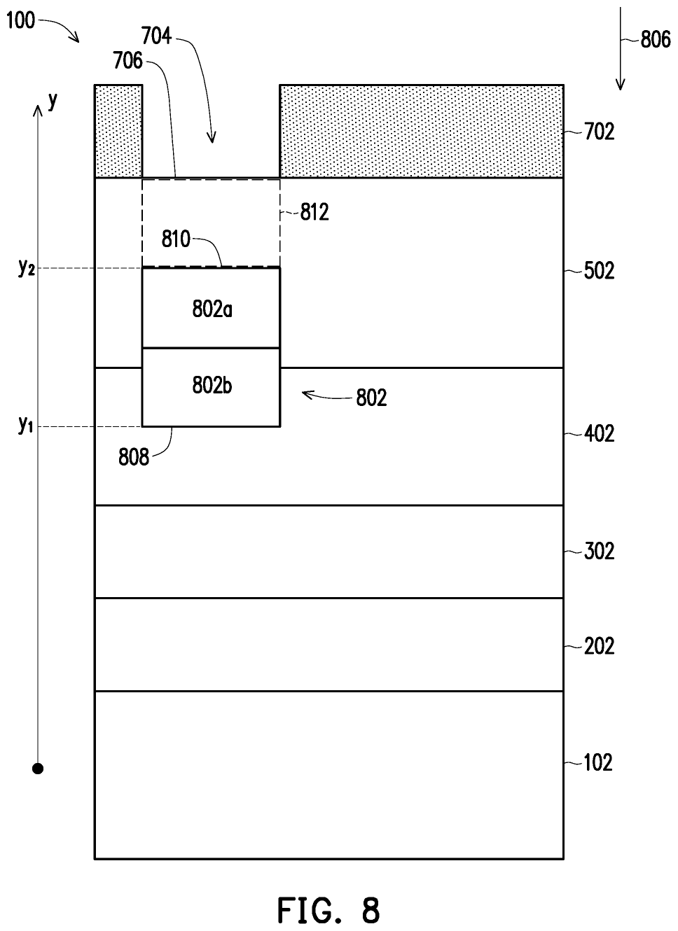

FIG. 8 illustrates use of the first patterned photoresist 702 to form a first doped region 802 having a second conductivity type in one or more epitaxial layers of the plurality of epitaxial layers, according to some embodiments. In some embodiments, the first conductivity type is p-type and the second conductivity type is n-type. Embodiments are contemplated in which the first conductivity type is n-type and the second conductivity type is p-type. In some embodiments, the first patterned photoresist 702 is used to dope a region 708 (shown with a dashed-line rectangle in FIG. 7), comprising a portion of the third epitaxial layer 402 and a portion of the fourth epitaxial layer 502, to form the first doped region 802 shown in FIG. 8. In some embodiments, the region 708 is counter-doped to form the first doped region 802. In some embodiments, the region 708 is doped to form the first doped region 802 by a first doping process comprising at least one of ion implantation, molecular diffusion, or other suitable techniques. In some embodiments, the first doping process comprises directing dopants having the second conductivity type through one or more portions of the top surface of the fourth epitaxial layer 502 that are laterally offset from the first patterned photoresist 702. In some embodiments, the dopants are n-type dopants comprising at least one of nitrogen dopants, phosphorus dopants, or other n-type dopants. In some embodiments, the first patterned photoresist 702 blocks dopants from entering a portion of the top surface of the fourth epitaxial layer 502 that is covered by the first patterned photoresist 702. In some embodiments, the first doping process comprises directing dopants having the second conductivity type through the portion 706 of the top surface of the fourth epitaxial layer 502 exposed by the opening 704. In some embodiments, a depth with which dopants penetrate into the semiconductor device 100 in the first doping process is controlled by increasing or decreasing a voltage used to direct the dopants into the semiconductor device 100. Other processes and techniques for at least one of doping the region 708 or forming the first doped region 802 are within the scope of the present disclosure. In some embodiments, the first doped region 802 has a gradient such that a concentration of dopants changes, such as increases or decreases along a first direction 806, such as a vertical direction along a y-axis. In some embodiments, the first doped region 802 underlies the opening 704 in the first patterned photoresist 702. In some embodiments, the first doped region 802 extends from a first side 808 at a first y-axis position y₁ on the y-axis to a second side 810 at a second y-axis position y₂. In some embodiments, at least one of the first y-axis position y₁ of the first side 808 of the first doped region 802 or the second y-axis position y₂ of the second side 810 of the first doped region 802 are controlled by at least one of a voltage, an implantation energy level, an implantation dose, etc. of the first doping process.

In some embodiments, the first doped region 802 comprises a first sub-region 802a and a second sub-region 802b. In some embodiments, the first sub-region 802a overlies the second sub-region 802b. In some embodiments, the first sub-region 802a corresponds to an n-region and the second sub-region 802b corresponds to a deep n-region. In some embodiments, the first sub-region 802a and the second sub-region 802b are doped at least one of concurrently or in the same process, such as the first doping process. Embodiments are contemplated in which the first sub-region 802a and the second sub-region 802b are doped in separate processes and/or acts. In some embodiments, a dopant concentration of dopants having the second conductivity type in the first sub-region 802a is different than a dopant concentration of dopants having the second conductivity type in the second sub-region 802b.

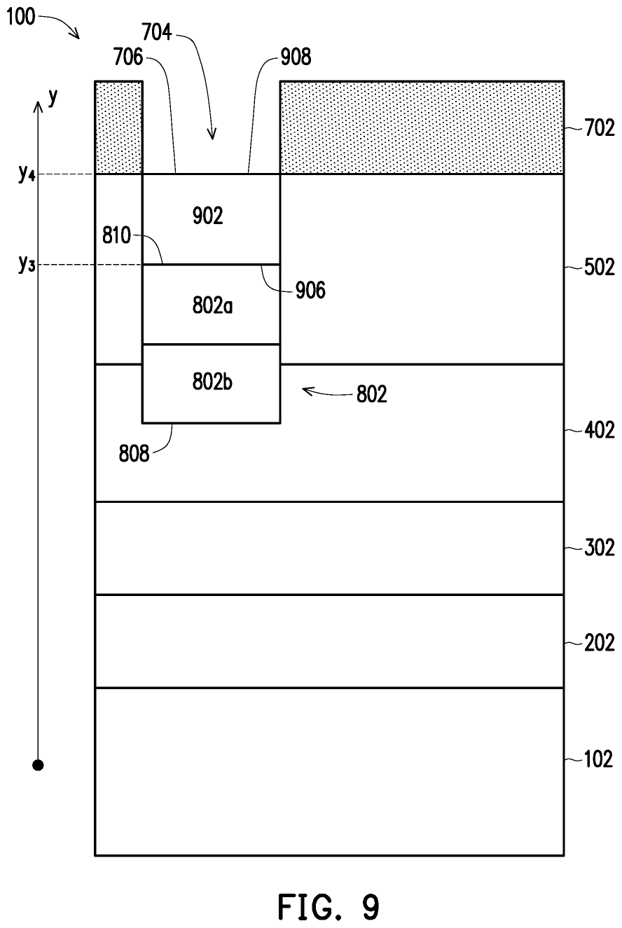

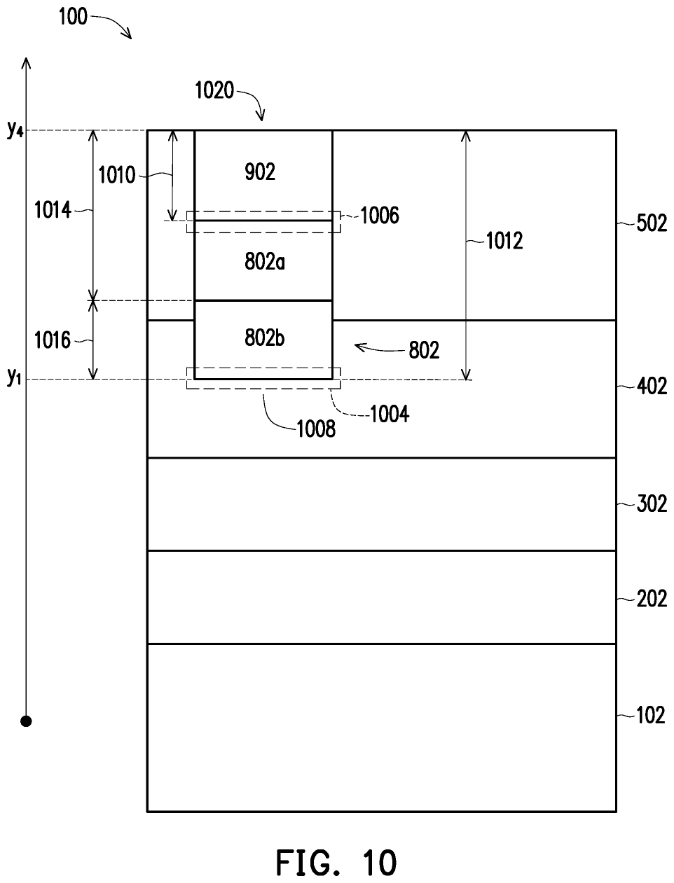

FIG. 9 illustrates use of the first patterned photoresist 702 to form a second doped region 902 having the first conductivity type in one or more epitaxial layers of the plurality of epitaxial layers, according to some embodiments. In some embodiments, the first patterned photoresist 702 is used to dope a region 812 (shown with a dashed-line rectangle in FIG. 8), comprising a portion of the fourth epitaxial layer 502, to form the second doped region 902 shown in FIG. 9. In some embodiments, the region 812 is doped to form the second doped region 902 by a second doping process comprising at least one of ion implantation, molecular diffusion, or other suitable techniques. In some embodiments, the second doping process comprises directing dopants having the first conductivity type through one or more portions of the top surface of the fourth epitaxial layer 502 that are laterally offset from the first patterned photoresist 702. In some embodiments, the second doping process comprises directing dopants having the first conductivity type through the portion 706 of the top surface of the fourth epitaxial layer 502 exposed by the opening 704 into at least one of the fourth epitaxial layer 502 or one or more epitaxial layers underlying the fourth epitaxial layer 502. In some embodiments, a depth with which dopants penetrate into the semiconductor device 100 in the second doping process is controlled by increasing or decreasing a voltage used to direct the dopants into the semiconductor device 100. Other processes and techniques for at least one of doping the region 812 or forming the second doped region 902 are within the scope of the present disclosure. In some embodiments, the second doped region 902 has a gradient such that a concentration of dopants changes, such as increases or decreases along the first direction 806 (shown in FIG. 8).

In some embodiments, the second doped region 902 underlies the opening 704 in the first patterned photoresist 702. In some embodiments, the second doped region 902 overlies the first doped region 802. In some embodiments, the second doped region 902 extends from a first side 906 at a third y-axis position y₃ to a second side 908 at a fourth y-axis position y₄. In some embodiments, at least one of the third y-axis position y₃ of the first side 906 of the second doped region 902 or the fourth y-axis position y₄ of the second side 908 of the second doped region 902 are controlled by at least one of a voltage, an implantation energy level, an implantation dose, etc. of the second doping process.

In some embodiments, the second doped region 902 is adjacent the first doped region 802. In some embodiments, the first side 906 of the second doped region 902 is aligned with the second side 810 of the first doped region 802. In some embodiments, the third y-axis position y₃ of the first side 906 of the second doped region 902 is about equal to the second y-axis position y₂ (shown in FIG. 8) of the second side 810 of the first doped region 802. In some embodiments, the third y-axis position y₃ is within a threshold distance of the second y-axis position y₂.

In some embodiments, the second doped region 902 is adjacent the portion 706 of the top surface of the fourth epitaxial layer 502. In some embodiments, the second side 908 of the second doped region 902 at least one of comprises or is aligned with the portion 706 of the top surface of the fourth epitaxial layer 502.

FIG. 10 illustrates removal of the first patterned photoresist 702, according to some embodiments. In some embodiments, the first patterned photoresist 702 is removed after the first doped region 802 and the second doped region 902 are formed. The first patterned photoresist 702 is removed by at least one of a washing process to wash the first patterned photoresist 702 away, stripping the first patterned photoresist 702 away, etching the first patterned photoresist 702, chemical mechanical planarization (CMP), or other suitable techniques.

In some embodiments, the first patterned photoresist 702 is removed after the first doping process performed to form the first doped region 802 and prior to the second doping process performed to form the second doped region 902. In some embodiments, a second patterned photoresist is formed after removing the first patterned photoresist 702. In some embodiments, the second patterned photoresist is formed using one or more of the techniques provided herein with respect to the first patterned photoresist 702. In some embodiments, the second patterned photoresist includes at least some of the features, relationships with other elements, etc. provided herein with respect to the first patterned photoresist 702. In some embodiments, the second patterned photoresist is used to form the second doped region 902 using one or more of the techniques provided herein with respect to using the first patterned photoresist 702 to form the second doped region 902.

Embodiments are contemplated in which a mask layer, such as a hard mask layer, is used to form at least one of the first doped region 802 or the second doped region 902. In some embodiments, a first mask layer (not shown) is formed over the fourth epitaxial layer 502. The first mask layer is formed by at least one of PVD, sputtering, CVD, PECVD, LPCVD, ALCVD, UHVCVD, RPCVD, ALD, MBE, LPE, spin on, growth, or other suitable techniques. In some embodiments, the first mask layer is a hard mask layer. The first mask layer comprises at least one of oxide, nitride, a metal, or other suitable material. The first mask layer is patterned to form a first patterned mask layer (not shown). In some embodiments, the first mask layer is patterned via an etching process. The etching process uses at least one of plasma, fluorine, hydrogen fluoride (HF), diluted HF, sulfur hexafluoride (SF₆), a chlorine compound such as hydrogen chloride (HCl₂), hydrogen sulfide (H₂S), tetrafluoromethane (CF₄), or other suitable material to remove one or more portions of the first mask layer to form the first patterned mask layer. In some embodiments, the first patterned mask layer includes at least some of the features, relationships with other elements, etc. provided herein with respect to the first patterned photoresist 702. In some embodiments, the first patterned mask layer is used to form the first doped region 802 using one or more of the techniques provided herein with respect to using the first patterned photoresist 702 to form the first doped region 802. In some embodiments, the first patterned mask layer is used to form the second doped region 902 using one or more of the techniques provided herein with respect to using the first patterned photoresist 702 to form the second doped region 902. In some embodiments, at least one of the first doping process or the second doping process is performed using the first patterned mask layer. In some embodiments, the first patterned mask layer is removed after the second doping process. In some embodiments, the first patterned mask layer is removed by at least one of CMP, a washing process, etching, or other suitable techniques.

In some embodiments, the first patterned mask layer is removed after the first doping process and prior to the second doping process. In some embodiments, a second patterned mask layer is formed after removing the first patterned mask layer. In some embodiments, the second patterned mask layer is formed using one or more of the techniques provided herein with respect to the first patterned mask layer. In some embodiments, the second patterned mask layer includes at least some of the features, relationships with other elements, etc. provided herein with respect to the first patterned mask layer. In some embodiments, the second patterned mask layer is used to form the second doped region 902 using one or more of the techniques provided herein with respect to using the first patterned photoresist 702 to form the second doped region 902.

Embodiments are contemplated in which at least some of the second doped region 902 is formed prior to at least some of the first doped region 802.

In some embodiments, a distance 1014 between the second sub-region 802b and the top surface of the fourth epitaxial layer 502 is at least about 1 micrometer. In some embodiments, a thickness 1016 of the second sub-region 802b is at least about 1 micrometer.

In some embodiments, the semiconductor device 100 comprises a first p-n junction 1004. In some embodiments, the first p-n junction 1004 is between the first doped region 802 and a portion 1008, of the third epitaxial layer 402, underlying the first doped region 802. In some embodiments, the first p-n junction 1004 is between the first side 808 (shown in FIGS. 8-9) of the first doped region 802 and the portion 1008, of the third epitaxial layer 402, underlying the first doped region 802. In some embodiments, the first p-n junction 1004 is formed due to the first doped region 802 having the second conductivity type different than the first conductivity type of the portion 1008 of the third epitaxial layer 402.

In some embodiments, the semiconductor device 100 comprises a second p-n junction 1006. In some embodiments, the second p-n junction 1006 is between the first doped region 802 and the second doped region 902. In some embodiments, the second p-n junction 1006 is between the second side 810 (shown in FIGS. 8-9) of the first doped region 802 and the first side 906 (shown in FIG. 9) of the second doped region 902. In some embodiments, the second p-n junction 1006 is formed due to the second doped region 902 having the first conductivity type different than the second conductivity type of the first doped region 802. Embodiments are contemplated in which the semiconductor device 100 comprises an intrinsic region (not shown) between the second side 810 (shown in FIGS. 8-9) of the first doped region 802 and the first side 906 (shown in FIG. 9) of the second doped region 902, thereby forming a PIN diode structure in the second p-n junction 1006.

In some embodiments, a photodiode 1020 comprises at least one of the first doped region 802, the second doped region 902, the first p-n junction 1004, the second p-n junction 1006, or the intrinsic region. In some embodiments, radiation is projected towards the semiconductor device 100, such as at least one of in the first direction 806 or in a different direction. At least some of the radiation is at least one of sensed, detected, or converted to electrons by the photodiode 1020. In some embodiments, the semiconductor device 100 comprises one or more layers (not shown) overlying the fourth epitaxial layer 502. In some embodiments, the one or more layers comprise at least one of a dielectric layer, a color filter layer, a lens array, or other suitable layer. In some embodiments, the lens array comprises a lens, such as a micro-lens or other suitable lens, overlying the photodiode 1020. In some embodiments, at least some of the radiation passes through the one or more layers and is at least one of sensed, detected, or converted to electrons by the photodiode 1020.

In some embodiments, radiation is converted to electrons using the first p-n junction 1004. In some embodiments, a pixel of an image is generated based upon a first metric associated with the electrons converted by the first p-n junction 1004. In some embodiments, the first metric is based upon at least one of an intensity, a charge, a current read out, etc. associated with the electrons converted by the first p-n junction 1004. In some embodiments, a first read out circuit (not shown) of the semiconductor device 100 is used to measure the electrons converted using the first p-n junction 1004 to determine the first metric.

In some embodiments, radiation is converted to electrons using the second p-n junction 1006. In some embodiments, a pixel of an image is generated based upon a first metric associated with the electrons converted by the second p-n junction 1006. In some embodiments, the first metric is based upon at least one of an intensity, a charge, a current read out, etc. associated with the electrons converted by the second p-n junction 1006. In some embodiments, a second read out circuit of the semiconductor device 100 is used to measure the electrons converted using the second p-n junction 1006 to determine the first metric. In some embodiments, the first read out circuit is the same as the second read out circuit. In some embodiments, the first read out circuit is different than the second read out circuit.

In some embodiments, the first p-n junction 1004 has a first depth 1012 relative to the top surface of the fourth epitaxial layer 502. In some embodiments, the first depth 1012 corresponds to a distance between the top surface of the fourth epitaxial layer 502 and the first side 808 of the first doped region 802. In some embodiments, the first depth 1012 corresponds to a distance between the fourth y-axis position y₄ and the first y-axis position y₁ of the first side 808 (shown in FIG. 8) of the first doped region 802. In some embodiments, an amount of radiation at least one of sensed, detected, or converted using the first p-n junction 1004 depends upon at least one of the first depth 1012 of the first p-n junction 1004 or a wavelength of the radiation. In some embodiments, the first p-n junction 1004 having the first depth 1012 enables the photodiode 1020 to at least one of sense, detect, or convert an increased amount of radiation having wavelengths within a first range of wavelengths, as compared to other depths other than the first depth 1012. In some embodiments, the first depth 1012 is within a first range of depths. In some embodiments, the first range of depths ranges from about 1 micrometer to about 25 micrometers. In some embodiments, the first range of depths ranges from about 8 micrometers to about 14 micrometers. In some embodiments, the first range of depths ranges from about 10 micrometers to about 12 micrometers. In some embodiments, the first p-n junction 1004 having the first depth 1012 within the first range of depths enables the photodiode 1020 to at least one of sense, detect, or convert an increased amount of radiation associated with the first range of wavelengths, as compared a p-n junction having a depth outside the first range of depths. In some embodiments, the first range of wavelengths comprises near-infrared (NIR) wavelengths. In some embodiments, the first range of wavelengths ranges from about 700 nanometers to about 2500 nanometers. In some embodiments, the first depth 1012 of the first p-n junction 1004 is based upon, such as fitted to, a penetration depth of photons associated with the first range of wavelengths to provide for improved detection of photons associated with the first range of wavelengths, such as due, at least in part, to an increased amount of overlap between the first doped region 802 and the photons' penetration path, thereby providing for increased absorption of the photons in the photodiode 1020. In some embodiments, NIR radiation has a NIR penetration depth of at least about 10 micrometers, such as where a NIR photon penetrates at least about 10 micrometers into the semiconductor device 100 before the NIR photon is absorbed. In some embodiments, the first depth 1012 of the first p-n junction 1004 is based upon, such as fitted to, the NIR penetration depth to provide for improved detection of NIR photons. Thus, in accordance with some embodiments, implementing the first p-n junction 1004 to have the first depth 1012 provides for an improved quantum efficiency (QE) for detecting radiation associated with the first range of wavelengths, such as NIR radiation. In some embodiments, a p-n junction that has a depth smaller than a minimum depth of the first range of depths does not efficiently sense, detect, and/or convert the NIR radiation. Given the improved QE associated with the first p-n junction 1004 having the first depth 1012, the sensor implemented via the semiconductor device 100 operates more efficiently than other sensors, such as requiring less power, being more effective in a relatively low light environment, providing a higher resolution, etc.

In some embodiments, the second p-n junction 1006 has a second depth 1010 relative to the top surface of the fourth epitaxial layer 502. In some embodiments, the second depth 1010 corresponds to a distance between the top surface of the fourth epitaxial layer 502 and at least one of the first side 906 (shown in FIG. 9) of the second doped region 902 or the second side 810 (shown in FIGS. 8-9) of the first doped region 802. In some embodiments, the second depth 1010 corresponds to a distance between the fourth y-axis position y₄ and the second y-axis position y₂ (shown in FIG. 8) of the second side 810 of the first doped region 802. In some embodiments, the second depth 1010 corresponds to a distance between the fourth y-axis position y₄ and the third y-axis position y₃ (shown in FIG. 9) of the first side 906 of the second doped region 902. In some embodiments, an amount of radiation at least one of sensed, detected, or converted using the second p-n junction 1006 depends upon at least one of the second depth 1010 of the second p-n junction 1006 or a wavelength of the radiation. In some embodiments, the second p-n junction 1006 having the second depth 1010 enables the photodiode 1020 to at least one of sense, detect, or convert an increased amount of radiation having wavelengths within a second range of wavelengths, as compared to other depths other than the second depth 1010. In some embodiments, the second depth 1010 is within a second range of depths. In some embodiments, the second range of depths ranges from about 0.5 micrometers to about 12 micrometers. In some embodiments, the second range of depths ranges from about 0.5 micrometers to about 8 micrometers. In some embodiments, the second p-n junction 1006 having the second depth 1010 within the second range of depths enables the photodiode 1020 to at least one of sense, detect, or convert an increased amount of radiation associated with the second range of wavelengths, as compared a p-n junction having a depth outside the second range of depths. In some embodiments, the second range of wavelengths comprises visible wavelengths. In some embodiments, the second range of wavelengths ranges from about 300 nanometers to about 800 nanometers. Thus, in accordance with some embodiments, implementing the second p-n junction 1006 to have the second depth 1010 provides for an improved QE for detecting radiation associated with the second range of wavelengths, such as visible light. Given the improved QE, the sensor implemented via the semiconductor device 100 operates more efficiently than other sensors, such as requiring less power, being more effective in a relatively low light environment, providing a higher resolution, etc.

In accordance with some embodiments, implementing the first p-n junction 1004 and the second p-n junction 1006 overlying the first p-n junction 1004 enables the semiconductor device 100 to (i) at least one of sense, detect, or convert radiation having wavelengths within the first range of wavelengths using the first p-n junction 1004, and (ii) at least one of sense, detect, or convert radiation having wavelengths within the second range of wavelengths using the second p-n junction 1006. In some embodiments, when the first range of wavelengths comprises NIR wavelengths and the second range of wavelengths comprises visible wavelengths, the sensor can (i) accurately sense NIR radiation in a low-light environment, such as at night or when the sensor is in a dark enclosed space, and (ii) accurately sense visible light in a high-light environment, such as at least one of during the day or when the sensor is in an environment with greater than a threshold amount of visible light. In some embodiments, implementing the first p-n junction 1004 to have the first depth 1012 enables the sensor to generate to an image with improved resolution when the sensor is in the low-light environment as compared to a sensor that does not include the first p-n junction 1004 having the first depth 1012. In some embodiments, implementing the second p-n junction 1006 to have the second depth 1010 enables the sensor to generate to an image with improved resolution when the sensor is in the high-light environment as compared to a sensor that does not include the second p-n junction 1006 having the second depth 1010. In some embodiments, the sensor is implemented in a vehicle, such as at least one of a car, an aircraft, production equipment, etc. In some embodiments, the vehicle is controlled based upon an image generated by the sensor. In some embodiments, the improved resolution of images generated by the sensor provides for improved reliability and/or safety of the vehicle when the vehicle is in at least one of the low-light environment or the high-light environment.

Although four epitaxial layers of the plurality of epitaxial layers are shown in FIG. 10, embodiments are contemplated in which the plurality of epitaxial layers comprise any quantity of epitaxial layers, such as two epitaxial layers, three epitaxial layers, five epitaxial layers, or more than five epitaxial layers. Although the first p-n junction 1004 is shown to be in the third epitaxial layer 402 in FIG. 10, embodiments are contemplated in which the first p-n junction 1004 is in any of the plurality of epitaxial layers, such as the first epitaxial layer 202, the second epitaxial layer 302, or the fourth epitaxial layer 502. Although the second p-n junction 1006 is shown to be in the fourth epitaxial layer 502 in FIG. 10, embodiments are contemplated in which the second p-n junction 1006 is in any of the plurality of epitaxial layers, such as the first epitaxial layer 202, the second epitaxial layer 302, or the third epitaxial layer 402. In some embodiments, the second p-n junction 1006 is in one of two uppermost epitaxial layers of the plurality of epitaxial layers, such as in the third epitaxial layer 402 or the fourth epitaxial layer 502.

In some embodiments, the plurality of epitaxial layers is formed with gradient dopant concentrations associated with the first conductivity type. In some embodiments, each epitaxial layer of one, some, or all of the plurality of epitaxial layers is formed to have a lesser dopant concentration of dopants of the first conductivity type than an underlying layer, such as another epitaxial layer of the plurality of epitaxial layers, that underlies the epitaxial layer. In some embodiments, at least one of (i) the first dopant concentration of the first dopants of the first conductivity type in the substrate 102 is greater than the second dopant concentration of the second dopants of the first conductivity type in the first epitaxial layer 202, (ii) the second dopant concentration of the second dopants of the first conductivity type in the first epitaxial layer 202 is greater than the third dopant concentration of the third dopants of the first conductivity type in the second epitaxial layer 302, (iii) the third dopant concentration of the third dopants of the first conductivity type in the second epitaxial layer 302 is greater than the fourth dopant concentration of the fourth dopants of the first conductivity type in the third epitaxial layer 402, or (iv) the fourth dopant concentration of the fourth dopants of the first conductivity type in the third epitaxial layer 402 is greater than the fifth dopant concentration of the fifth dopants of the first conductivity type in the fourth epitaxial layer 502.

In some embodiments, the plurality of epitaxial layers is formed with gradient thicknesses. In some embodiments, each epitaxial layer of one, some, or all of the plurality of epitaxial layers is formed to have a greater thickness than an underlying layer, such as another epitaxial layer of the plurality of epitaxial layers, that underlies the epitaxial layer. In some embodiments, at least one of (i) the second thickness 304 of the second epitaxial layer 302 is greater than the first thickness 204 of the first epitaxial layer 202, (ii) the third thickness 404 of the third epitaxial layer 402 is greater than the second thickness 304 of the second epitaxial layer 302, or (iii) the fourth thickness 504 of the fourth epitaxial layer 502 is greater than the third thickness 404 of the third epitaxial layer 402. In some embodiments, an uppermost epitaxial layer of the plurality of epitaxial layers has a thickness of at least 3 micrometers, such as a thickness of at least 5 micrometers or a thickness of at least 5.5 micrometers. In some embodiments, the uppermost epitaxial layer of the plurality of epitaxial layers is the fourth epitaxial layer 502, wherein the fourth thickness 504 (shown in FIG. 5) of the fourth epitaxial layer 502 is at least 3 micrometers, at least 5 micrometers, or at least 5.5 micrometers.

In some embodiments, the first p-n junction 1004 has a third depth relative to a top surface of a first layer of the one or more layers (not shown) overlying the fourth epitaxial layer 502. In some embodiments, the first layer of the one or more layers corresponds to an uppermost layer of the one or more layers. In some embodiments, the first layer of the one or more layers comprises the lens array. In some embodiments, the third depth corresponds to a distance between a vertical position of the top surface of the first layer and a vertical position of the first p-n junction 1004. In some embodiments, the third depth corresponds to a distance between the vertical position of the top surface of the first layer and a vertical position, such as the first y-axis position y₁ shown in FIG. 8, of the first side 808 of the first doped region 802. In some embodiments, the third depth is within a third range of depths. In some embodiments, the third range of depths ranges from about 1 micrometer to about 50 micrometers. In some embodiments, the third range of depths ranges from about 8 micrometers to about 14 micrometers. In some embodiments, the third range of depths ranges from about 10 micrometers to about 12 micrometers.

In some embodiments, the second p-n junction 1006 has a fourth depth relative to the top surface of the first layer of the one or more layers (not shown) overlying the fourth epitaxial layer 502. In some embodiments, the fourth depth corresponds to a distance between the vertical position of the top surface of the first layer and a vertical position of the second p-n junction 1006. In some embodiments, the fourth depth corresponds to a distance between the vertical position of the top surface of the first layer and a vertical position, such as the second y-axis position y₂ shown in FIG. 8, of the second side 810 of the first doped region 802. In some embodiments, the fourth depth corresponds to a distance between the vertical position of the top surface of the first layer and a vertical position, such as the third y-axis position y₃ shown in FIG. 9, of the first side 906 of the second doped region 902. In some embodiments, the fourth depth is within a fourth range of depths. In some embodiments, the fourth range of depths ranges from about 0.5 micrometers to about 30 micrometers. In some embodiments, the fourth range of depths ranges from about 0.5 micrometers to about 8 micrometers.

In some embodiments, the substrate 102 and the plurality of epitaxial layers comprise silicon or other suitable material. In some embodiments, the first conductivity type is p-type and the second conductivity type is n-type. In some embodiments, each epitaxial layer of at least some of the plurality of epitaxial layers comprises p-type dopants comprising at least one of boron dopants, aluminum dopants, gallium dopants, beryllium dopants, or other p-type dopants. In some embodiments, a first p-type dopant concentration of p-type dopants in the first epitaxial layer 202 is greater than a second p-type dopant concentration of p-type dopants in the second epitaxial layer 302. In some embodiments, the second p-type dopant concentration of p-type dopants in the second epitaxial layer 302 is greater than a third p-type dopant concentration of p-type dopants in the third epitaxial layer 402. In some embodiments, the third p-type dopant concentration of p-type dopants in the third epitaxial layer 402 is greater than a fourth p-type dopant concentration of p-type dopants in the fourth epitaxial layer 502. In some embodiments, the fourth p-type dopant concentration corresponds to an average concentration of p-type dopants across at least a portion of the fourth epitaxial layer 502. In some embodiments, a p-type dopant concentration of p-type dopants in the second doped region 902 is greater than at least one of the first p-type dopant concentration, the second p-type dopant concentration, the third p-type dopant concentration, or the fourth p-type dopant concentration. In some embodiments, a p-type dopant concentration of p-type dopants in the substrate 102 is greater than a p-type dopant concentration of p-type dopants in each epitaxial layer of the plurality of epitaxial layers. In some embodiments, the p-type dopant concentration of p-type dopants in the substrate 102 is greater than at least one of the first p-type dopant concentration, the second p-type dopant concentration, the third p-type dopant concentration, or the fourth p-type dopant concentration.

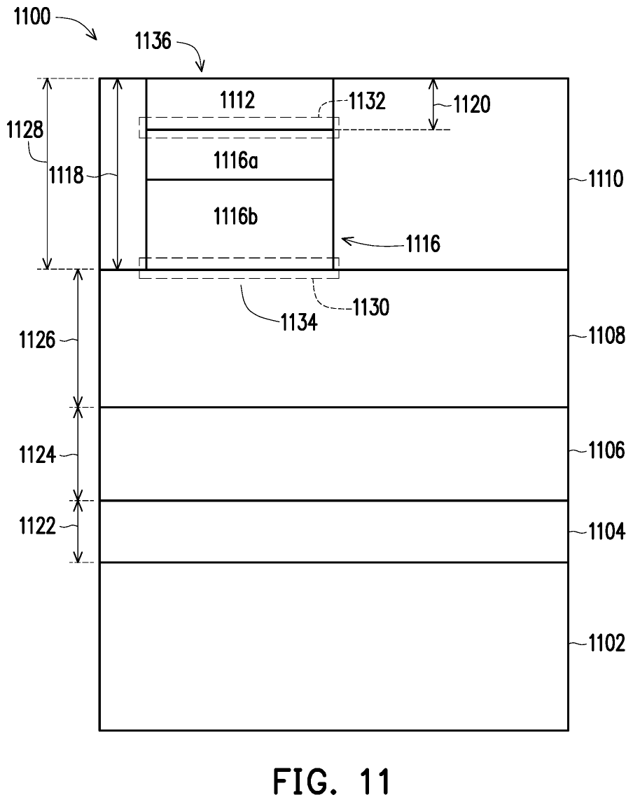

FIG. 11 illustrates a semiconductor device 1100 according to some embodiments. In some embodiments, the semiconductor device 1100 is formed using one or more of the techniques provided herein with respect to forming the semiconductor device 100 (shown in FIGS. 1-10). In some embodiments, a component of the semiconductor device 1100 includes at least some of the features, relationships with other elements, etc. provided herein with respect to the semiconductor device 100 (shown in FIGS. 1-10). In some embodiments, the semiconductor device 1100 comprises a substrate 1102 and a plurality of epitaxial layers comprising at least one of a first epitaxial layer 1104 over the substrate 1102, a second epitaxial layer 1106 over the first epitaxial layer 1104, a third epitaxial layer 1108 over the second epitaxial layer 1106, or a fourth epitaxial layer 1110 over the third epitaxial layer 1108. Although four epitaxial layers of the plurality of epitaxial layers are shown in FIG. 11, embodiments are contemplated in which the plurality of epitaxial layers comprise any quantity of epitaxial layers, such as two epitaxial layers, three epitaxial layers, five epitaxial layers, or more than five epitaxial layers.

In some embodiments, each epitaxial layer of one, some, or all of the plurality of epitaxial layers is formed to have a greater thickness than an underlying layer, such as another epitaxial layer of the plurality of epitaxial layers, that underlies the epitaxial layer. In some embodiments, at least one of (i) the second epitaxial layer 1106 is formed to have a thickness 1124 greater than a thickness 1122 of the first epitaxial layer 1104, (ii) the third epitaxial layer 1108 is formed to have a thickness 1126 greater than the thickness 1124 of the second epitaxial layer 1106, or (iii) the fourth epitaxial layer 1110 is formed to have a thickness 1128 greater than the thickness 1126 of the third epitaxial layer 1108.

In some embodiments, the substrate 1102 comprises first dopants having the first conductivity type. In some embodiments, each epitaxial layer of one, some, or all of the plurality of epitaxial layers is formed to have a lesser dopant concentration of dopants of the first conductivity type than an underlying layer, such as another epitaxial layer of the plurality of epitaxial layers, that underlies the epitaxial layer. In some embodiments, at least one of (i) a first dopant concentration of the first dopants of the first conductivity type in the substrate 1102 is greater than a second dopant concentration of second dopants of the first conductivity type in the first epitaxial layer 1104, (ii) the second dopant concentration of the second dopants of the first conductivity type in the first epitaxial layer 1104 is greater than a third dopant concentration of third dopants of the first conductivity type in the second epitaxial layer 1106, (iii) the third dopant concentration of the third dopants of the first conductivity type in the second epitaxial layer 1106 is greater than a fourth dopant concentration of fourth dopants of the first conductivity type in the third epitaxial layer 1108, or (iv) the fourth dopant concentration of the fourth dopants of the first conductivity type in the third epitaxial layer 1108 is greater than a fifth dopant concentration of fifth dopants of the first conductivity type in the fourth epitaxial layer 1110.

In some embodiments, the semiconductor device 1100 comprises a first doped region 1116 and a second doped region 1112. In some embodiments, the first doped region 1116 is formed using one or more of the techniques provided herein with respect to forming the first doped region 802 (shown in FIG. 8). In some embodiments, the second doped region 1112 is formed using one or more of the techniques provided herein with respect to forming the second doped region 902 (shown in FIG. 9). In some embodiments, the first doped region 1116 has the second conductivity type different than the first conductivity type. In some embodiments, the first conductivity type is p-type and the second conductivity type is n-type. Embodiments are contemplated in which the first conductivity type is n-type and the second conductivity type is p-type. In some embodiments, the first doped region 1116 comprises a first sub-region 1116a and a second sub-region 1116b. In some embodiments, the first sub-region 1116a overlies the second sub-region 1116b. In some embodiments, the first sub-region 1116a corresponds to an n-region and the second sub-region 1116b corresponds to a deep n-region.

In some embodiments, the semiconductor device 1100 comprises a first p-n junction 1130. In some embodiments, the first p-n junction 1130 is between the first doped region 1116 and a portion 1134, of at least one of the fourth epitaxial layer 1110 or the third epitaxial layer 1108, underlying the first doped region 1116. In some embodiments, the first p-n junction 1130 is in at least one of the fourth epitaxial layer 1110 or the third epitaxial layer 1108. In some embodiments, the first p-n junction 1130 comprises an interface between the fourth epitaxial layer 1110 and the third epitaxial layer 1108. In some embodiments, the first p-n junction 1130 is formed due to the first doped region 1116 having the second conductivity type different than the first conductivity type of the portion 1134 of at least one of the fourth epitaxial layer 1110 or the third epitaxial layer 1108. In some embodiments, the first p-n junction 1130 has a first depth 1118 relative to a top surface of the fourth epitaxial layer 1110.

In some embodiments, the semiconductor device 1100 comprises a second p-n junction 1132. In some embodiments, the second p-n junction 1132 is between the first doped region 1116 and the second doped region 1112. In some embodiments, the second p-n junction 1132 is in the fourth epitaxial layer 1110. In some embodiments, the second p-n junction 1132 is formed due to the second doped region 1112 having the first conductivity type different than the second conductivity type of the first doped region 1116. Embodiments are contemplated in which the semiconductor device 1100 comprises an intrinsic region (not shown) between the first doped region 1116 and the second doped region 1112, thereby forming a PIN diode structure in the second p-n junction 1132. In some embodiments, the second p-n junction 1132 has a second depth 1120 relative to the top surface of the fourth epitaxial layer 1110.

In some embodiments, a photodiode 1136 of the semiconductor device 1100 comprises at least one of the first doped region 1116, the second doped region 1112, the first p-n junction 1130, or the second p-n junction 1132.

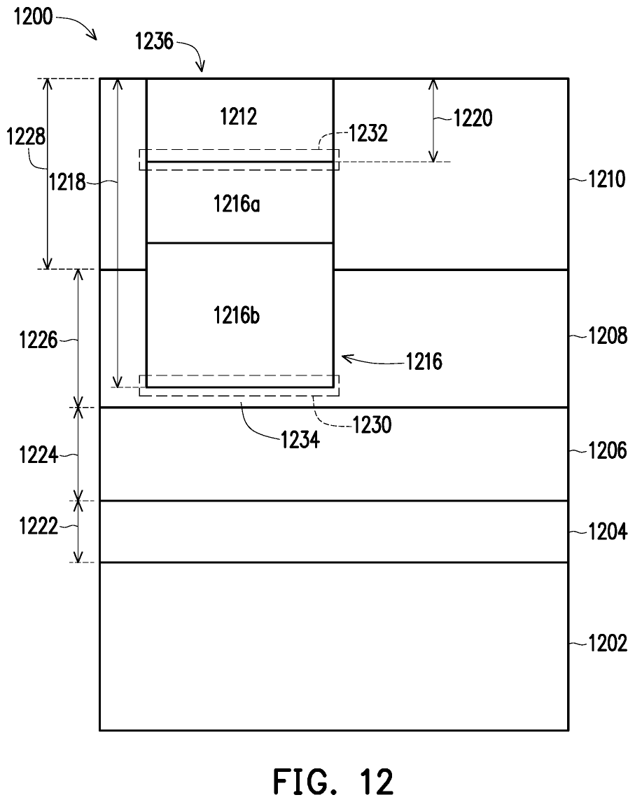

FIG. 12 illustrates a semiconductor device 1200 according to some embodiments. In some embodiments, the semiconductor device 1200 is formed using one or more of the techniques provided herein with respect to forming the semiconductor device 100 (shown in FIGS. 1-10). In some embodiments, a component of the semiconductor device 1200 includes at least some of the features, relationships with other elements, etc. provided herein with respect to the semiconductor device 100 (shown in FIGS. 1-10). In some embodiments, the semiconductor device 1200 comprises a substrate 1202 and a plurality of epitaxial layers comprising at least one of a first epitaxial layer 1204 over the substrate 1202, a second epitaxial layer 1206 over the first epitaxial layer 1204, a third epitaxial layer 1208 over the second epitaxial layer 1206, or a fourth epitaxial layer 1210 over the third epitaxial layer 1208. Although four epitaxial layers of the plurality of epitaxial layers are shown in FIG. 12, embodiments are contemplated in which the plurality of epitaxial layers comprise any quantity of epitaxial layers, such as two epitaxial layers, three epitaxial layers, five epitaxial layers, or more than five epitaxial layers.

In some embodiments, each epitaxial layer of one, some, or all of the plurality of epitaxial layers is formed to have a greater thickness than an underlying layer, such as another epitaxial layer of the plurality of epitaxial layers, that underlies the epitaxial layer. In some embodiments, at least one of (i) the second epitaxial layer 1206 is formed to have a thickness 1224 greater than a thickness 1222 of the first epitaxial layer 1204, (ii) the third epitaxial layer 1208 is formed to have a thickness 1226 greater than the thickness 1224 of the second epitaxial layer 1206, or (iii) the fourth epitaxial layer 1210 is formed to have a thickness 1228 greater than the thickness 1226 of the third epitaxial layer 1208.

In some embodiments, the substrate 1202 comprises first dopants of the first conductivity type. In some embodiments, each epitaxial layer of one, some, or all of the plurality of epitaxial layers is formed to have a lesser dopant concentration of dopants of the first conductivity type than an underlying layer, such as another epitaxial layer of the plurality of epitaxial layers, that underlies the epitaxial layer. In some embodiments, at least one of (i) a first dopant concentration of the first dopants of the first conductivity type in the substrate 1202 is greater than a second dopant concentration of second dopants of the first conductivity type in the first epitaxial layer 1204, (ii) the second dopant concentration of the second dopants of the first conductivity type in the first epitaxial layer 1204 is greater than a third dopant concentration of third dopants of the first conductivity type in the second epitaxial layer 1206, (iii) the third dopant concentration of the third dopants of the first conductivity type in the second epitaxial layer 1206 is greater than a fourth dopant concentration of fourth dopants of the first conductivity type in the third epitaxial layer 1208, or (iv) the fourth dopant concentration of the fourth dopants of the first conductivity type in the third epitaxial layer 1208 is greater than a fifth dopant concentration of fifth dopants of the first conductivity type in the fourth epitaxial layer 1210.

In some embodiments, the semiconductor device 1200 comprises a first doped region 1216 and a second doped region 1212. In some embodiments, the first doped region 1216 is formed using one or more of the techniques provided herein with respect to forming the first doped region 802 (shown in FIG. 8). In some embodiments, the second doped region 1212 is formed using one or more of the techniques provided herein with respect to forming the second doped region 902 (shown in FIG. 9). In some embodiments, the first doped region 1216 has the second conductivity type different than the first conductivity type. In some embodiments, the first conductivity type is p-type and the second conductivity type is n-type. Embodiments are contemplated in which the first conductivity type is n-type and the second conductivity type is p-type. In some embodiments, the first doped region 1216 comprises a first sub-region 1216a and a second sub-region 1216b. In some embodiments, the first sub-region 1216a overlies the second sub-region 1216b. In some embodiments, the first sub-region 1216a corresponds to an n-region and the second sub-region 1216b corresponds to a deep n-region.

In some embodiments, the semiconductor device 1200 comprises a first p-n junction 1230. In some embodiments, the first p-n junction 1230 is between the first doped region 1216 and a portion 1234, of the third epitaxial layer 1208, underlying the first doped region 1216. In some embodiments, the first p-n junction 1230 is in the third epitaxial layer 1208. In some embodiments, the first p-n junction 1230 is formed due to the first doped region 1216 having the second conductivity type different than the first conductivity type of the portion 1234 of the third epitaxial layer 1208. In some embodiments, the first p-n junction 1230 has a first depth 1218 relative to a top surface of the fourth epitaxial layer 1210.

In some embodiments, the semiconductor device 1200 comprises a second p-n junction 1232. In some embodiments, the second p-n junction 1232 is between the first doped region 1216 and the second doped region 1212. In some embodiments, the second p-n junction 1232 is in the fourth epitaxial layer 1210. In some embodiments, the second p-n junction 1232 is formed due to the second doped region 1212 having the first conductivity type different than the second conductivity type of the first doped region 1216. Embodiments are contemplated in which the semiconductor device 1200 comprises an intrinsic region (not shown) between the first doped region 1216 and the second doped region 1212, thereby forming a PIN diode structure in the second p-n junction 1232. In some embodiments, the second p-n junction 1232 has a second depth 1220 relative to the top surface of the fourth epitaxial layer 1210.

In some embodiments, a photodiode 1236 of the semiconductor device 1200 comprises at least one of the first doped region 1216, the second doped region 1212, the first p-n junction 1230, or the second p-n junction 1232.

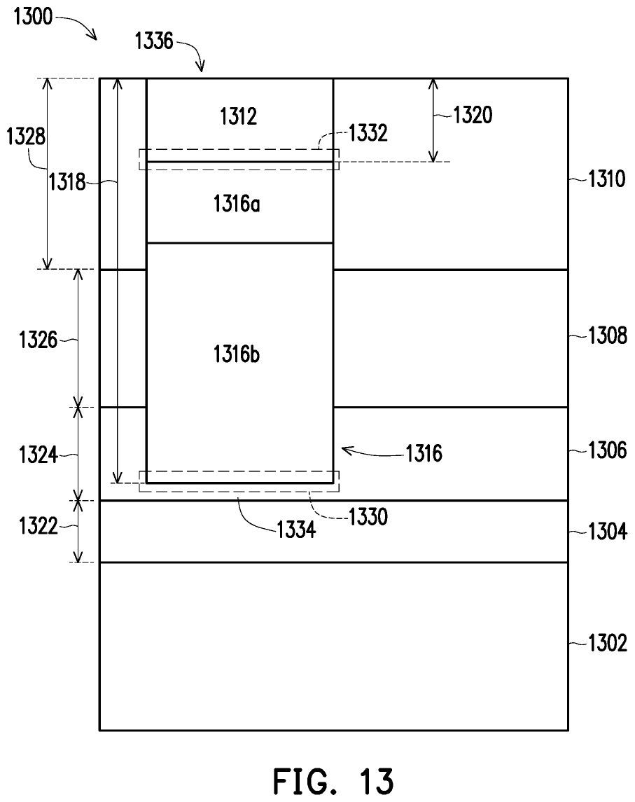

FIG. 13 illustrates a semiconductor device 1300 according to some embodiments. In some embodiments, the semiconductor device 1300 is formed using one or more of the techniques provided herein with respect to forming the semiconductor device 100 (shown in FIGS. 1-10). In some embodiments, a component of the semiconductor device 1300 includes at least some of the features, relationships with other elements, etc. provided herein with respect to the semiconductor device 100 (shown in FIGS. 1-10). In some embodiments, the semiconductor device 1300 comprises a substrate 1302 and a plurality of epitaxial layers comprising at least one of a first epitaxial layer 1304 over the substrate 1302, a second epitaxial layer 1306 over the first epitaxial layer 1304, a third epitaxial layer 1308 over the second epitaxial layer 1306, or a fourth epitaxial layer 1310 over the third epitaxial layer 1308. Although four epitaxial layers of the plurality of epitaxial layers are shown in FIG. 13, embodiments are contemplated in which the plurality of epitaxial layers comprise any quantity of epitaxial layers, such as two epitaxial layers, three epitaxial layers, five epitaxial layers, or more than five epitaxial layers.

In some embodiments, each epitaxial layer of one, some, or all of the plurality of epitaxial layers is formed to have a greater thickness than an underlying layer, such as another epitaxial layer of the plurality of epitaxial layers, that underlies the epitaxial layer. In some embodiments, at least one of (i) the second epitaxial layer 1306 is formed to have a thickness 1324 greater than a thickness 1322 of the first epitaxial layer 1304, (ii) the third epitaxial layer 1308 is formed to have a thickness 1326 greater than the thickness 1324 of the second epitaxial layer 1306, or (iii) the fourth epitaxial layer 1310 is formed to have a thickness 1328 greater than the thickness 1326 of the third epitaxial layer 1308.

In some embodiments, the substrate 1302 comprises first dopants of the first conductivity type. In some embodiments, each epitaxial layer of one, some, or all of the plurality of epitaxial layers is formed to have a lesser dopant concentration of dopants of the first conductivity type than an underlying layer, such as another epitaxial layer of the plurality of epitaxial layers, that underlies the epitaxial layer. In some embodiments, at least one of (i) a first dopant concentration of the first dopants of the first conductivity type in the substrate 1302 is greater than a second dopant concentration of second dopants of the first conductivity type in the first epitaxial layer 1304, (ii) the second dopant concentration of the second dopants of the first conductivity type in the first epitaxial layer 1304 is greater than a third dopant concentration of third dopants of the first conductivity type in the second epitaxial layer 1306, (iii) the third dopant concentration of the third dopants of the first conductivity type in the second epitaxial layer 1306 is greater than a fourth dopant concentration of fourth dopants of the first conductivity type in the third epitaxial layer 1308, or (iv) the fourth dopant concentration of the fourth dopants of the first conductivity type in the third epitaxial layer 1308 is greater than a fifth dopant concentration of fifth dopants of the first conductivity type in the fourth epitaxial layer 1310.

In some embodiments, the semiconductor device 1300 comprises a first doped region 1316 and a second doped region 1312. In some embodiments, the first doped region 1316 is formed using one or more of the techniques provided herein with respect to forming the first doped region 802 (shown in FIG. 8). In some embodiments, the second doped region 1312 is formed using one or more of the techniques provided herein with respect to forming the second doped region 902 (shown in FIG. 9). In some embodiments, the first doped region 1316 has the second conductivity type different than the first conductivity type. In some embodiments, the first conductivity type is p-type and the second conductivity type is n-type. Embodiments are contemplated in which the first conductivity type is n-type and the second conductivity type is p-type. In some embodiments, the first doped region 1316 comprises a first sub-region 1316a and a second sub-region 1316b. In some embodiments, the first sub-region 1316a overlies the second sub-region 1316b. In some embodiments, the first sub-region 1316a corresponds to an n-region and the second sub-region 1316b corresponds to a deep n-region.

In some embodiments, the semiconductor device 1300 comprises a first p-n junction 1330. In some embodiments, the first p-n junction 1330 is between the first doped region 1316 and a portion 1334, of the second epitaxial layer 1306, underlying the first doped region 1316. In some embodiments, the first p-n junction 1330 is in the second epitaxial layer 1306. In some embodiments, the first p-n junction 1330 is formed due to the first doped region 1316 having the second conductivity type different than the first conductivity type of the portion 1334 of the second epitaxial layer 1306. In some embodiments, the first p-n junction 1330 has a first depth 1318 relative to a top surface of the fourth epitaxial layer 1310.

In some embodiments, the semiconductor device 1300 comprises a second p-n junction 1332. In some embodiments, the second p-n junction 1332 is between the first doped region 1316 and the second doped region 1312. In some embodiments, the second p-n junction 1332 is in the fourth epitaxial layer 1310. In some embodiments, the second p-n junction 1332 is formed due to the second doped region 1312 having the first conductivity type different than the second conductivity type of the first doped region 1316. Embodiments are contemplated in which the semiconductor device 1300 comprises an intrinsic region (not shown) between the first doped region 1316 and the second doped region 1312, thereby forming a PIN diode structure in the second p-n junction 1332. In some embodiments, the second p-n junction 1332 has a second depth 1320 relative to the top surface of the fourth epitaxial layer 1310.

In some embodiments, a photodiode 1336 of the semiconductor device 1300 comprises at least one of the first doped region 1316, the second doped region 1312, the first p-n junction 1330, or the second p-n junction 1332.

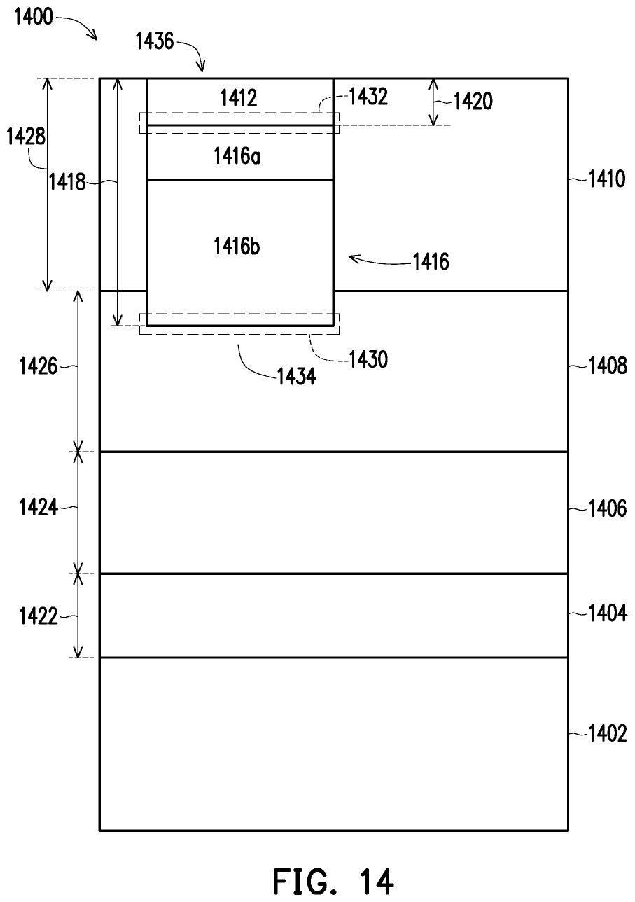

FIG. 14 illustrates a semiconductor device 1400 according to some embodiments. In some embodiments, the semiconductor device 1400 is formed using one or more of the techniques provided herein with respect to forming the semiconductor device 100 (shown in FIGS. 1-10). In some embodiments, a component of the semiconductor device 1400 includes at least some of the features, relationships with other elements, etc. provided herein with respect to the semiconductor device 100 (shown in FIGS. 1-10). In some embodiments, the semiconductor device 1400 comprises a substrate 1402 and a plurality of epitaxial layers comprising at least one of a first epitaxial layer 1404 over the substrate 1402, a second epitaxial layer 1406 over the first epitaxial layer 1404, a third epitaxial layer 1408 over the second epitaxial layer 1406, or a fourth epitaxial layer 1410 over the third epitaxial layer 1408. Although four epitaxial layers of the plurality of epitaxial layers are shown in FIG. 14, embodiments are contemplated in which the plurality of epitaxial layers comprise any quantity of epitaxial layers, such as two epitaxial layers, three epitaxial layers, five epitaxial layers, or more than five epitaxial layers.

In some embodiments, each epitaxial layer of one, some, or all of the plurality of epitaxial layers is formed to have a greater thickness than an underlying layer, such as another epitaxial layer of the plurality of epitaxial layers, that underlies the epitaxial layer. In some embodiments, at least one of (i) the second epitaxial layer 1406 is formed to have a thickness 1424 greater than a thickness 1422 of the first epitaxial layer 1404, (ii) the third epitaxial layer 1408 is formed to have a thickness 1426 greater than the thickness 1424 of the second epitaxial layer 1406, or (iii) the fourth epitaxial layer 1410 is formed to have a thickness 1428 greater than the thickness 1426 of the third epitaxial layer 1408.

In some embodiments, the substrate 1402 comprises first dopants of the first conductivity type. In some embodiments, each epitaxial layer of one, some, or all of the plurality of epitaxial layers is formed to have a lesser dopant concentration of dopants of the first conductivity type than an underlying layer, such as another epitaxial layer of the plurality of epitaxial layers, that underlies the epitaxial layer. In some embodiments, at least one of (i) a first dopant concentration of the first dopants of the first conductivity type in the substrate 1402 is greater than a second dopant concentration of second dopants of the first conductivity type in the first epitaxial layer 1404, (ii) the second dopant concentration of the second dopants of the first conductivity type in the first epitaxial layer 1404 is greater than a third dopant concentration of third dopants of the first conductivity type in the second epitaxial layer 1406, (iii) the third dopant concentration of the third dopants of the first conductivity type in the second epitaxial layer 1406 is greater than a fourth dopant concentration of fourth dopants of the first conductivity type in the third epitaxial layer 1408, or (iv) the fourth dopant concentration of the fourth dopants of the first conductivity type in the third epitaxial layer 1408 is greater than a fifth dopant concentration of fifth dopants of the first conductivity type in the fourth epitaxial layer 1410.

In some embodiments, the semiconductor device 1400 comprises a first doped region 1416 and a second doped region 1412. In some embodiments, the first doped region 1416 is formed using one or more of the techniques provided herein with respect to forming the first doped region 802 (shown in FIG. 8). In some embodiments, the second doped region 1412 is formed using one or more of the techniques provided herein with respect to forming the second doped region 902 (shown in FIG. 9). In some embodiments, the first doped region 1416 has the second conductivity type different than the first conductivity type. In some embodiments, the first conductivity type is p-type and the second conductivity type is n-type. Embodiments are contemplated in which the first conductivity type is n-type and the second conductivity type is p-type. In some embodiments, the first doped region 1416 comprises a first sub-region 1416a and a second sub-region 1416b. In some embodiments, the first sub-region 1416a overlies the second sub-region 1416b. In some embodiments, the first sub-region 1416a corresponds to an n-region and the second sub-region 1416b corresponds to a deep n-region.

In some embodiments, the semiconductor device 1400 comprises a first p-n junction 1430. In some embodiments, the first p-n junction 1430 is between the first doped region 1416 and a portion 1434, of the third epitaxial layer 1408, underlying the first doped region 1416. In some embodiments, the first p-n junction 1430 is in the third epitaxial layer 1408. In some embodiments, the first p-n junction 1430 is formed due to the first doped region 1416 having the second conductivity type different than the first conductivity type of the portion 1434 of the third epitaxial layer 1408. In some embodiments, the first p-n junction 1430 has a first depth 1418 relative to a top surface of the fourth epitaxial layer 1410.

In some embodiments, the semiconductor device 1400 comprises a second p-n junction 1432. In some embodiments, the second p-n junction 1432 is between the first doped region 1416 and the second doped region 1412. In some embodiments, the second p-n junction 1432 is in the fourth epitaxial layer 1410. In some embodiments, the second p-n junction 1432 is formed due to the second doped region 1412 having the first conductivity type different than the second conductivity type of the first doped region 1416. Embodiments are contemplated in which the semiconductor device 1400 comprises an intrinsic region (not shown) between the first doped region 1416 and the second doped region 1412, thereby forming a PIN diode structure in the second p-n junction 1432. In some embodiments, the second p-n junction 1432 has a second depth 1420 relative to the top surface of the fourth epitaxial layer 1410.

In some embodiments, a photodiode 1436 of the semiconductor device 1400 comprises at least one of the first doped region 1416, the second doped region 1412, the first p-n junction 1430, or the second p-n junction 1432.

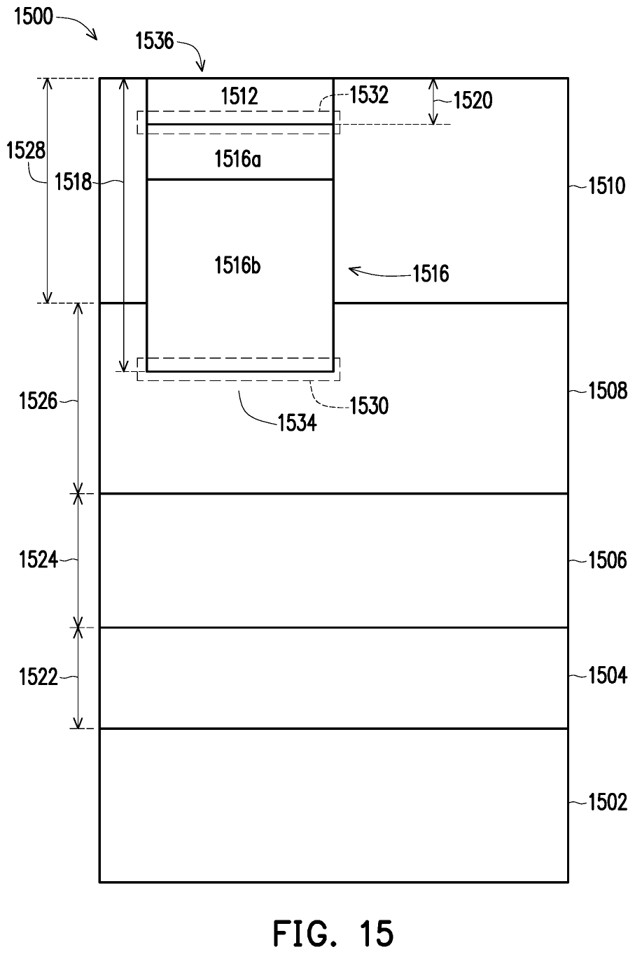

FIG. 15 illustrates a semiconductor device 1500 according to some embodiments. In some embodiments, the semiconductor device 1500 is formed using one or more of the techniques provided herein with respect to forming the semiconductor device 100 (shown in FIGS. 1-10). In some embodiments, a component of the semiconductor device 1500 includes at least some of the features, relationships with other elements, etc. provided herein with respect to the semiconductor device 100 (shown in FIGS. 1-10). In some embodiments, the semiconductor device 1500 comprises a substrate 1502 and a plurality of epitaxial layers comprising at least one of a first epitaxial layer 1504 over the substrate 1502, a second epitaxial layer 1506 over the first epitaxial layer 1504, a third epitaxial layer 1508 over the second epitaxial layer 1506, or a fourth epitaxial layer 1510 over the third epitaxial layer 1508. Although four epitaxial layers of the plurality of epitaxial layers are shown in FIG. 15, embodiments are contemplated in which the plurality of epitaxial layers comprise any quantity of epitaxial layers, such as two epitaxial layers, three epitaxial layers, five epitaxial layers, or more than five epitaxial layers.

In some embodiments, each epitaxial layer of one, some, or all of the plurality of epitaxial layers is formed to have a greater thickness than an underlying layer, such as another epitaxial layer of the plurality of epitaxial layers, that underlies the epitaxial layer. In some embodiments, at least one of (i) the second epitaxial layer 1506 is formed to have a thickness 1524 greater than a thickness 1522 of the first epitaxial layer 1504, (ii) the third epitaxial layer 1508 is formed to have a thickness 1526 greater than the thickness 1524 of the second epitaxial layer 1506, or (iii) the fourth epitaxial layer 1510 is formed to have a thickness 1528 greater than the thickness 1526 of the third epitaxial layer 1508.

In some embodiments, the substrate 1502 comprises first dopants of the first conductivity type. In some embodiments, each epitaxial layer of one, some, or all of the plurality of epitaxial layers is formed to have a lesser dopant concentration of dopants of the first conductivity type than an underlying layer, such as another epitaxial layer of the plurality of epitaxial layers, that underlies the epitaxial layer. In some embodiments, at least one of (i) a first dopant concentration of the first dopants of the first conductivity type in the substrate 1502 is greater than a second dopant concentration of second dopants of the first conductivity type in the first epitaxial layer 1504, (ii) the second dopant concentration of the second dopants of the first conductivity type in the first epitaxial layer 1504 is greater than a third dopant concentration of third dopants of the first conductivity type in the second epitaxial layer 1506, (iii) the third dopant concentration of the third dopants of the first conductivity type in the second epitaxial layer 1506 is greater than a fourth dopant concentration of fourth dopants of the first conductivity type in the third epitaxial layer 1508, or (iv) the fourth dopant concentration of the fourth dopants of the first conductivity type in the third epitaxial layer 1508 is greater than a fifth dopant concentration of fifth dopants of the first conductivity type in the fourth epitaxial layer 1510.

In some embodiments, the semiconductor device 1500 comprises a first doped region 1516 and a second doped region 1512. In some embodiments, the first doped region 1516 is formed using one or more of the techniques provided herein with respect to forming the first doped region 802 (shown in FIG. 8). In some embodiments, the second doped region 1512 is formed using one or more of the techniques provided herein with respect to forming the second doped region 902 (shown in FIG. 9). In some embodiments, the first doped region 1516 has the second conductivity type different than the first conductivity type. In some embodiments, the first conductivity type is p-type and the second conductivity type is n-type. Embodiments are contemplated in which the first conductivity type is n-type and the second conductivity type is p-type. In some embodiments, the first doped region 1516 comprises a first sub-region 1516a and a second sub-region 1516b. In some embodiments, the first sub-region 1516a overlies the second sub-region 1516b. In some embodiments, the first sub-region 1516a corresponds to an n-region and the second sub-region 1516b corresponds to a deep n-region.

In some embodiments, the semiconductor device 1500 comprises a first p-n junction 1530. In some embodiments, the first p-n junction 1530 is between the first doped region 1516 and a portion 1534, of the third epitaxial layer 1508, underlying the first doped region 1516. In some embodiments, the first p-n junction 1530 is in the third epitaxial layer 1508. In some embodiments, the first p-n junction 1530 is formed due to the first doped region 1516 having the second conductivity type different than the first conductivity type of the portion 1534 of the third epitaxial layer 1508. In some embodiments, the first p-n junction 1530 has a first depth 1518 relative to a top surface of the fourth epitaxial layer 1510.

In some embodiments, the semiconductor device 1500 comprises a second p-n junction 1532. In some embodiments, the second p-n junction 1532 is between the first doped region 1516 and the second doped region 1512. In some embodiments, the second p-n junction 1532 is in the fourth epitaxial layer 1510. In some embodiments, the second p-n junction 1532 is formed due to the second doped region 1512 having the first conductivity type different than the second conductivity type of the first doped region 1516. Embodiments are contemplated in which the semiconductor device 1500 comprises an intrinsic region (not shown) between the first doped region 1516 and the second doped region 1512, thereby forming a PIN diode structure in the second p-n junction 1532. In some embodiments, the second p-n junction 1532 has a second depth 1520 relative to the top surface of the fourth epitaxial layer 1510.

In some embodiments, a photodiode 1536 of the semiconductor device 1500 comprises at least one of the first doped region 1516, the second doped region 1512, the first p-n junction 1530, or the second p-n junction 1532.

In some embodiments, a QE of a sensor implemented using one or more of the techniques provided herein is dependent upon a first depth of a first p-n junction in the sensor. In some embodiments, the first depth corresponds to at least one of the first depth 1012 of the first p-n junction 1004 of the semiconductor device 100 shown in FIG. 10, the first depth 1118 of the first p-n junction 1130 of the semiconductor device 1100 shown in FIG. 11, the first depth 1218 of the first p-n junction 1230 of the semiconductor device 1200 shown in FIG. 12, the first depth 1318 of the first p-n junction 1330 of the semiconductor device 1300 shown in FIG. 13, the first depth 1418 of the first p-n junction 1430 of the semiconductor device 1400 shown in FIG. 14, or the first depth 1518 of the first p-n junction 1530 of the semiconductor device 1500 shown in FIG. 15. In some embodiments, at least one of the first depth 1012 shown in FIG. 10, the first depth 1118 shown in FIG. 11, the first depth 1218 shown in FIG. 12, the first depth 1318 shown in FIG. 13, the first depth 1418 shown in FIG. 14, or the first depth 1518 shown in FIG. 15 are within the first range of depths, such as from about 1 micrometer to about 25 micrometers, from about 8 micrometers to about 14 micrometers, or from about 10 micrometers to about 12 micrometers. In some embodiments, increasing the first depth provides for improved QE of the sensor, such as improved NIR QE for detecting NIR radiation. In some embodiments, a sensor implemented via the semiconductor device 1200 shown in FIG. 12 has an improved QE, such as an improved NIR QE, compared to a sensor implemented via the semiconductor device 1100 based upon the first depth 1218 of the first p-n junction 1230 being greater than the first depth 1118 of the first p-n junction 1130 shown in FIG. 11. In some embodiments, a sensor implemented via the semiconductor device 1300 shown in FIG. 13 has an improved QE, such as an improved NIR QE, compared to a sensor implemented via the semiconductor device 1200-1100 based upon the first depth 1318 of the first p-n junction 1330 being greater than the first depth 1218 of the first p-n junction 1230 shown in FIG. 12.

In some embodiments, a QE of a sensor implemented using one or more of the techniques provided herein is dependent upon a dopant concentration parameter associated with a plurality of epitaxial layers in the sensor. In some embodiments, the dopant concentration parameter corresponds to a dopant concentration of dopants having the first conductivity type in an uppermost epitaxial layer of the plurality of epitaxial layers. In some embodiments, the dopant concentration parameter corresponds to a dopant concentration of dopants having the first conductivity type in a lowermost epitaxial layer of the plurality of epitaxial layers. In some embodiments, the dopant concentration parameter corresponds to a dopant concentration of dopants having the first conductivity type in a region of the plurality of epitaxial layers, wherein the region at least one of is within a threshold distance of a top surface of an uppermost epitaxial layer of the plurality of epitaxial layers or comprises at least some of one or more epitaxial layers of the plurality of epitaxial layers. In some embodiments, the dopant concentration parameter corresponds to a dopant concentration of dopants having the first conductivity type in a region of the plurality of epitaxial layers, wherein the region at least one of is within a threshold distance of a bottom surface of a lowermost epitaxial layer of the plurality of epitaxial layers or comprises at least some of one or more epitaxial layers of the plurality of epitaxial layers. In some embodiments, the dopant concentration parameter corresponds to a dopant concentration of dopants of the first conductivity type in a portion, of an epitaxial layer, that underlies the first p-n junction, such as at least one of the portion 1008 of the third epitaxial layer 402, the portion 1134 of at least one of the fourth epitaxial layer 1110 or the third epitaxial layer 1108, the portion 1234 of the third epitaxial layer 1208, the portion 1334 of the second epitaxial layer 1306, the portion 1434 of the third epitaxial layer 1408, or the portion 1534 of the third epitaxial layer 1508. In some embodiments, the dopant concentration parameter corresponds to at least one of a first dopant concentration parameter associated with the plurality of epitaxial layers of the semiconductor device 100 shown in FIG. 10, a second dopant concentration parameter associated with the plurality of epitaxial layers of the semiconductor device 1100 shown in FIG. 11, a third dopant concentration parameter associated with the plurality of epitaxial layers of the semiconductor device 1200 shown in FIG. 12, a fourth dopant concentration parameter associated with the plurality of epitaxial layers of the semiconductor device 1300 shown in FIG. 13, a fifth dopant concentration parameter associated with the plurality of epitaxial layers of the semiconductor device 1400 shown in FIG. 14, or a sixth dopant concentration parameter associated with the plurality of epitaxial layers of the semiconductor device 1500 shown in FIG. 15. In some embodiments, a reduction of the dopant concentration parameter provides for improved QE of the sensor, such as improved NIR QE for detecting NIR radiation. In some embodiments, the reduction of the dopant concentration parameter provides for a reduction of dopants having the first conductivity type in a path through which dopants having the second conductivity type path are directed to form a first doped region of the sensor, such as at least one of the first doped region 802 (shown in FIG. 8), the first doped region 1116 (shown in FIG. 11), the first doped region 1216 (shown in FIG. 12), the first doped region 1316 (shown in FIG. 13), the first doped region 1416 (shown in FIG. 14), or the first doped region 1516 (shown in FIG. 15). In some embodiments, the reduction of the dopants having the first conductivity type in the path allows for an increase in penetration depth of the dopants having the second conductivity type in a doping process, such as the first doping process shown in and/or discussed with respect to FIG. 8. In some embodiments, the increase in penetration depth of the dopants provides for a greater depth of a first p-n junction of the sensor, such as at least one of the first p-n junction 1004 of the semiconductor device 100 shown in FIG. 10, the first p-n junction 1130 of the semiconductor device 1100 shown in FIG. 11, the first p-n junction 1230 of the semiconductor device 1200 shown in FIG. 12, the first p-n junction 1330 of the semiconductor device 1300 shown in FIG. 13, the first p-n junction 1430 of the semiconductor device 1400 shown in FIG. 14, or the first p-n junction 1530 of the semiconductor device 1500 shown in FIG. 15. In some embodiments, a sensor implemented via the semiconductor device 1200 shown in FIG. 12 has an improved QE, such as an improved NIR QE, compared to a sensor implemented via the semiconductor device 1100 based upon the third dopant concentration parameter associated with the semiconductor device 1200 shown in FIG. 12 being greater than the second dopant concentration parameter associated with the semiconductor device 1100 shown in FIG. 11. In some embodiments, a sensor implemented via the semiconductor device 1300 shown in FIG. 13 has an improved QE, such as an improved NIR QE, compared to a sensor implemented via the semiconductor device 1200 based upon the fourth dopant concentration parameter associated with the semiconductor device 1300 shown in FIG. 13 being greater than the third dopant concentration parameter associated with the semiconductor device 1200 shown in FIG. 12.

In some embodiments, a QE of a sensor implemented using one or more of the techniques provided herein is dependent upon a thickness parameter associated with a plurality of epitaxial layers in the sensor. In some embodiments, the thickness parameter corresponds to a thickness of an uppermost epitaxial layer of the plurality of epitaxial layers. In some embodiments, the thickness parameter corresponds to a thickness of a lowermost epitaxial layer of the plurality of epitaxial layers. In some embodiments, the thickness parameter corresponds to a combination of thicknesses of some or all epitaxial layers of the plurality of epitaxial layers. In some embodiments, the thickness parameter corresponds to a total thickness the plurality of epitaxial layers. In some embodiments, the thickness parameter corresponds to an average thickness of some or all epitaxial layers of the plurality of epitaxial layers. In some embodiments, the thickness parameter corresponds to a difference between a thickness of an epitaxial layer of the plurality of epitaxial layers and an underlying layer underlying the epitaxial layer. In some embodiments, the thickness parameter corresponds to at least one of a first thickness parameter associated with the plurality of epitaxial layers of the semiconductor device 100 shown in FIG. 10, a second thickness parameter associated with the plurality of epitaxial layers of the semiconductor device 1100 shown in FIG. 11, a third thickness parameter associated with the plurality of epitaxial layers of the semiconductor device 1200 shown in FIG. 12, a fourth thickness parameter associated with the plurality of epitaxial layers of the semiconductor device 1300 shown in FIG. 13, a fifth thickness parameter associated with the plurality of epitaxial layers of the semiconductor device 1400 shown in FIG. 14, or a sixth thickness parameter associated with the plurality of epitaxial layers of the semiconductor device 1500 shown in FIG. 15. In some embodiments, increasing the thickness parameter provides for improved QE of the sensor, such as improved NIR QE for detecting NIR radiation. In some embodiments, the increase of the thickness parameter provides for a reduction of dopants having the first conductivity type in a path through which dopants having the second conductivity type path are directed to form a first doped region of the sensor, such as at least one of the first doped region 802 (shown in FIG. 8), the first doped region 1116 (shown in FIG. 11), the first doped region 1216 (shown in FIG. 12), the first doped region 1316 (shown in FIG. 13), the first doped region 1416 (shown in FIG. 14), or the first doped region 1516 (shown in FIG. 15). In some embodiments, the reduction of the dopants having the first conductivity type in the path allows for an increase in penetration depth of the dopants having the second conductivity type in a doping process, such as the first doping process shown in and/or discussed with respect to FIG. 8. In some embodiments, the increase in penetration depth of the dopants provides for a greater depth of a first p-n junction of the sensor, such as at least one of the first p-n junction 1004 of the semiconductor device 100 shown in FIG. 10, the first p-n junction 1130 of the semiconductor device 1100 shown in FIG. 11, the first p-n junction 1230 of the semiconductor device 1200 shown in FIG. 12, the first p-n junction 1330 of the semiconductor device 1300 shown in FIG. 13, the first p-n junction 1430 of the semiconductor device 1400 shown in FIG. 14, or the first p-n junction 1530 of the semiconductor device 1500 shown in FIG. 15.

In some embodiments, a sensor implemented via the semiconductor device 1400 shown in FIG. 14 has an improved QE, such as an improved NIR QE, compared to a sensor implemented via the semiconductor device 1100 based upon the fifth thickness parameter associated with the semiconductor device 1400 shown in FIG. 14 being greater than the second thickness parameter associated with the semiconductor device 1100 shown in FIG. 11. In some embodiments, at least one of (i) a dopant concentration of dopants of the first conductivity type in the first epitaxial layer 1404 of the semiconductor device 1400 shown in FIG. 14 is about equal to a dopant concentration of dopants of the first conductivity type in the first epitaxial layer 1104 of the semiconductor device 1100 shown in FIG. 11, (ii) a dopant concentration of dopants of the first conductivity type in the second epitaxial layer 1406 of the semiconductor device 1400 shown in FIG. 14 is about equal to a dopant concentration of dopants of the first conductivity type in the second epitaxial layer 1106 of the semiconductor device 1100 shown in FIG. 11, (iii) a dopant concentration of dopants of the first conductivity type in the third epitaxial layer 1408 of the semiconductor device 1400 shown in FIG. 14 is about equal to a dopant concentration of dopants of the first conductivity type in the third epitaxial layer 1108 of the semiconductor device 1100 shown in FIG. 11, or (iv) a dopant concentration of dopants of the first conductivity type in the fourth epitaxial layer 1410 of the semiconductor device 1400 shown in FIG. 14 is about equal to a dopant concentration of dopants of the first conductivity type in the fourth epitaxial layer 1110 of the semiconductor device 1100 shown in FIG. 11.

In some embodiments, a sensor implemented via the semiconductor device 1500 shown in FIG. 15 has an improved QE, such as an improved NIR QE, compared to a sensor implemented via the semiconductor device 1400 based upon the sixth thickness parameter associated with the semiconductor device 1500 shown in FIG. 15 being greater than the fifth thickness parameter associated with the semiconductor device 1400 shown in FIG. 14. In some embodiments, at least one of (i) a dopant concentration of dopants of the first conductivity type in the first epitaxial layer 1504 of the semiconductor device 1500 shown in FIG. 15 is about equal to a dopant concentration of dopants of the first conductivity type in the first epitaxial layer 1404 of the semiconductor device 1400 shown in FIG. 14, (ii) a dopant concentration of dopants of the first conductivity type in the second epitaxial layer 1506 of the semiconductor device 1500 shown in FIG. 15 is about equal to a dopant concentration of dopants of the first conductivity type in the second epitaxial layer 1406 of the semiconductor device 1400 shown in FIG. 14, (iii) a dopant concentration of dopants of the first conductivity type in the third epitaxial layer 1508 of the semiconductor device 1500 shown in FIG. 15 is about equal to a dopant concentration of dopants of the first conductivity type in the third epitaxial layer 1408 of the semiconductor device 1400 shown in FIG. 14, or (iv) a dopant concentration of dopants of the first conductivity type in the fourth epitaxial layer 1510 of the semiconductor device 1500 shown in FIG. 15 is about equal to a dopant concentration of dopants of the first conductivity type in the fourth epitaxial layer 1410 of the semiconductor device 1400 shown in FIG. 14.

In some embodiments, a semiconductor device is provided. The semiconductor device includes a substrate including first dopants having a first conductivity type. The semiconductor device includes a first epitaxial layer over the substrate. The first epitaxial layer includes second dopants having the first conductivity type. The semiconductor device includes a second epitaxial layer over the first epitaxial layer. The second epitaxial layer includes third dopants having the first conductivity type. The semiconductor device includes a photodiode in at least one of the first epitaxial layer or the second epitaxial layer. The photodiode includes a first doped region having a second conductivity type different than the first conductivity type and a second doped region, over the first doped region, having the first conductivity type.

In some embodiments, a method for forming a semiconductor device is provided. The method includes forming a first epitaxial layer over a substrate. The method includes forming a second epitaxial layer over the first epitaxial layer. The method includes forming a photodiode in at least one of the first epitaxial layer or the second epitaxial layer.

In some embodiments, a semiconductor device is provided. The semiconductor device includes a substrate, a first epitaxial layer over the substrate, a second epitaxial layer over the first epitaxial layer, and a photodiode in at least one of the first epitaxial layer or the second epitaxial layer. The photodiode includes a first doped region and a second doped region over the first doped region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

1. A semiconductor device, comprising:
a substrate comprising first dopants having a first conductivity type;
a first epitaxial layer over the substrate and comprising second dopants having the first conductivity type;
a second epitaxial layer over the first epitaxial layer and comprising third dopants having the first conductivity type; and
a photodiode in at least one of the first epitaxial layer or the second epitaxial layer, wherein the photodiode comprises:
a first doped region having a second conductivity type different than the first conductivity type; and
a second doped region, over the first doped region, having the first conductivity type.

2. The semiconductor device of claim 1, wherein:
a first thickness of the first epitaxial layer is less than a second thickness of the second epitaxial layer.

3. The semiconductor device of claim 1, wherein:
a first concentration of the first dopants is greater than a second concentration of the second dopants.

4. The semiconductor device of claim 1, wherein the photodiode comprises:
a p-n junction between the first doped region and the second doped region.

5. The semiconductor device of claim 1, wherein the photodiode comprises:
an intrinsic region between the first doped region and the second doped region.

6. The semiconductor device of claim 1, comprising:
a p-n junction between the first doped region and a portion, of the second epitaxial layer, underlying the first doped region.

7. The semiconductor device of claim 1, comprising:
a p-n junction between the first doped region and a portion, of the first epitaxial layer, underlying the first doped region.

8. A method of forming a semiconductor device, comprising:
forming a first epitaxial layer over a substrate;
forming a second epitaxial layer over the first epitaxial layer; and
forming a photodiode in at least one of the first epitaxial layer or the second epitaxial layer.

9. The method of claim 8, wherein:
the substrate comprises first dopants having a first conductivity type;
forming the first epitaxial layer comprises forming the first epitaxial layer to comprise second dopants having the first conductivity type;
forming the second epitaxial layer comprises forming the second epitaxial layer to comprise third dopants having the first conductivity type; and
forming the photodiode comprises:
forming a first doped region having a second conductivity type in the second epitaxial layer, wherein the second conductivity type is different than the first conductivity type; and
forming a second doped region having the first conductivity type in the second epitaxial layer, wherein:
the second doped region overlies the first doped region; and
forming the first doped region forms a p-n junction between the first doped region and a portion, of at least one of the first epitaxial layer or the second epitaxial layer, underlying the first doped region.

10. The method of claim 8, wherein:
the substrate comprises first dopants having a first conductivity type;
forming the first epitaxial layer comprises forming the first epitaxial layer to comprise second dopants having the first conductivity type;
forming the second epitaxial layer comprises forming the second epitaxial layer to comprise third dopants having the first conductivity type; and
forming the photodiode comprises:
forming a first doped region having a second conductivity type in the first epitaxial layer, wherein the second conductivity type is different than the first conductivity type; and
forming a second doped region having the first conductivity type in the second epitaxial layer, wherein:
the second doped region overlies the first doped region; and
forming the first doped region forms a p-n junction between the first doped region and a portion, of the second epitaxial layer, underlying the first doped region.

11. The method of claim 8, wherein:
the substrate comprises a first concentration of first dopants having a first conductivity type;
forming the first epitaxial layer comprises forming the first epitaxial layer to comprise a second concentration of second dopants having the first conductivity type; and
forming the second epitaxial layer comprises forming the second epitaxial layer to comprise a third concentration of third dopants having the first conductivity type, wherein the second concentration is greater than the third concentration.

12. The method of claim 8, wherein forming the first epitaxial layer comprises:
forming the first epitaxial layer to have a first thickness that is less than a second thickness of the second epitaxial layer.

13. A semiconductor device, comprising:
a substrate;
a first epitaxial layer over the substrate;
a second epitaxial layer over the first epitaxial layer; and
a photodiode in at least one of the first epitaxial layer or the second epitaxial layer, wherein the photodiode comprises:
a first doped region; and
a second doped region over the first doped region.

14. The semiconductor device of claim 13, wherein:
a first thickness of the first epitaxial layer is less than a second thickness of the second epitaxial layer.

15. The semiconductor device of claim 13, wherein:
a first concentration of first dopants in the first epitaxial layer is greater than a second concentration of second dopants in the second epitaxial layer.

16. The semiconductor device of claim 13, wherein the photodiode comprises:
a p-n junction between the first doped region and the second doped region.

17. The semiconductor device of claim 13, wherein the photodiode comprises:
an intrinsic region between the first doped region and the second doped region.

18. The semiconductor device of claim 13, comprising:
a p-n junction between the first doped region and a portion, of at least one of the first epitaxial layer or the second epitaxial layer, underlying the first doped region.

19. The semiconductor device of claim 13, wherein:
the substrate comprises p-type dopants;
the first epitaxial layer comprises p-type dopants;
the second epitaxial layer comprises p-type dopants;
the first doped region comprises n-type dopants; and
the second doped region comprises p-type dopants.

20. The semiconductor device of claim 19, wherein:
a first concentration of the p-type dopants in the first epitaxial layer is greater than a second concentration of the p-type dopants in the second epitaxial layer.
